(19) United States
(12) Patent Application Publication
(10) Pub. No.: US 2025/0125261 A1
(43) Pub. Date: Apr. 17, 2025

(54) SEMICONDUCTOR STRUCTURES WITH MULTI-STAGE VIAS

(71) Applicant: International Business Machines Corporation, Armonk, NY (US)

(72) Inventors: Biswanath Senapati, Mechanicville, NY (US); Shahrukh Khan, Sandy Hook, CT (US); Utkarsh Bajpai, Delmar, NY (US); Ruilong Xie, Niskayuna, NY (US); Indira Seshadri, Niskayuna, NY (US); Tenko Yamashita, Schenectady, NY (US)

(21) Appl. No.: 18/488,236

(22) Filed: Oct. 17, 2023

(51) Int. Cl. H01L 23/528; H01L 21/8234; H01L 23/522; H01L 27/088; H01L 29/06; H01L 29/423; H01L 29/775; H01L 29/786

(52) U.S. Cl. CPC H01L 23/5283; H01L 23/5226; H10D 30/43; H10D 30/6735; H10D 30/6757; H10D 62/121; H10D 84/0149; H10D 84/038; H10D 84/83

(57) ABSTRACT

A method includes forming a first stage of a multi-stage via in a semiconductor structure utilizing processing from a first side of the semiconductor structure, the first stage of the multi-stage via having a first surface and a second surface opposite the first surface. The method also includes forming a second stage of the multi-stage via utilizing processing from a second side of the semiconductor structure, the first stage of the multi-stage via having a first surface and a second surface opposite the first surface. The first surface of the first stage of the multi-stage via is proximate the first side of the semiconductor structure, the first surface of the second stage of the multi-stage via is proximate the second side of the semiconductor structure, and the second surface of the first stage of the multi-stage via abuts the second surface of the second stage of the multi-stage via.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of Silicon Germanium (SiGe), between sheets of channel material, which may be formed of Silicon (Si).

For continued scaling and area improvement, stacked transistor structures may be used. A stacked transistor structure may include multiple transistors stacked over one another vertically. With stacked transistor structures, for example, via which extend between the frontside and the backside may have a high aspect ratio. The formation of high aspect ratio vias, however, presents various process challenges.

### SUMMARY

Embodiments of the invention provide techniques for forming multi-stage vias in semiconductor structures.

In one embodiment, a semiconductor structure comprises a multi-stage via comprising a first stage and a second stage. The first stage of the multi-stage via has a first surface and a second surface, the first surface of the first stage of the multi-stage via having a first diameter and the second surface of the first stage of the multi-stage via having a second diameter, the second diameter of the second surface of the first stage of the multi-stage via being smaller than or equal to the first diameter of the first surface of the first stage of the multi-stage via. The second stage of the multi-stage via has a first surface and a second surface, the first surface of the second stage of the multi-stage via having a first diameter and the second surface of the second stage of the multi-stage via having a second diameter, the second diameter of the second surface of the second stage of the multi-stage via being smaller than or equal to the first diameter of the first surface of the second stage of the multi-stage via. The first surface of the first stage of the multi-stage via is proximate a first side of the semiconductor structure and the first surface of the second stage of the multi-stage via is proximate a second side of the semiconductor structure, the second side of the semiconductor structure being opposite the first side of the semiconductor structure. The second surface of the first stage of the multi-stage via abuts the second surface of the second stage of the multi-stage via. The multi-stage via advantageously provides lower resistance (e.g., relative to a single-stage via), with resulting improvements in device performance.

The multi-stage via may provide power delivery from a power delivery network at the second side of the semiconductor structure to a portion of a transistor structure proximate the first side of the semiconductor structure. The multi-stage via may alternatively provide a signal connection between the first side of the semiconductor structure and the second side of the semiconductor structure.

The second surface of the first stage of the multi-stage via may abut the second surface of the second stage of the multi-stage via proximate a midpoint between the first side of the semiconductor structure and the second side of the semiconductor structure.

In another embodiment, an integrated circuit comprises a semiconductor structure comprising a multi-stage via comprising a first stage and a second stage. The first stage of the multi-stage via has a first surface and a second surface, the first surface of the first stage of the multi-stage via having a first diameter and the second surface of the first stage of the multi-stage via having a second diameter, the second diameter of the second surface of the first stage of the multi-stage via being smaller than or equal to the first diameter of the first surface of the first stage of the multi-stage via. The second stage of the multi-stage via has a first surface and a second surface, the first surface of the second stage of the multi-stage via having a first diameter and the second surface of the second stage of the multi-stage via having a second diameter, the second diameter of the second surface of the second stage of the multi-stage via being smaller than or equal to the first diameter of the first surface of the second stage of the multi-stage via. The first surface of the first stage of the multi-stage via is proximate a first side of the semiconductor structure and the first surface of the second stage of the multi-stage via is proximate a second side of the semiconductor structure, the second side of the semiconductor structure being opposite the first side of the semiconductor structure. The second surface of the first stage of the multi-stage via abuts the second surface of the second stage of the multi-stage via. The multi-stage via advantageously provides lower resistance (e.g., relative to a single-stage via), with resulting improvements in device performance.

The multi-stage via may provide power delivery from a power delivery network at the second side of the semiconductor structure to a portion of a transistor structure proximate the first side of the semiconductor structure. The multi-stage via may alternatively provide a signal connection between the first side of the semiconductor structure and the second side of the semiconductor structure.

The second surface of the first stage of the multi-stage via may abut the second surface of the second stage of the multi-stage via proximate a midpoint between the first side of the semiconductor structure and the second side of the semiconductor structure.

In another embodiment, a semiconductor structure comprises a stacked transistor structure comprising a first transistor vertically stacked over a second transistor and a multi-stage via comprising a first stage and a second stage. The first transistor is proximate a first side of the semiconductor structure and the second transistor is proximate a second side of the semiconductor structure opposite the first side of the semiconductor structure. Each of the first stage and the second stage of the multi-stage via has a first surface and a second surface opposite the first surface, the first surface of the first stage of the multi-stage via being proximate the first side of the semiconductor structure, the first surface of the first stage of the multi-stage via being proximate the second side of the semiconductor structure, and the second surface of the first stage of the multi-stage via abutting the second surface of the second stage of the multi-stage via. The multi-stage via connects a power delivery network proximate the second side of the semiconductor structure to a source/drain region of the first transistor. A first diameter of the first surface of the first stage of the multi-stage via is greater than or equal to a second diameter of the second surface of the second stage of the multi-stage via. A first diameter of the first surface of the second stage of the multi-stage via is greater than or equal to a second diameter of the second surface of the second stage of the multi-stage via. The multi-stage via advantageously provides lower resistance (e.g., relative to a single-stage via), with resulting improvements in device performance.

The second surface of the first stage of the multi-stage via may abut the second surface of the second stage of the multi-stage via proximate a midpoint between the first side of the semiconductor structure and the second side of the semiconductor structure.

In another embodiment, a semiconductor structure comprises a first back-end-of-line structure proximate a first side of the semiconductor structure, a second back-end-of-line structure proximate a second side of the semiconductor structure opposite the first side of the semiconductor structure, and a multi-stage via comprising a first stage and a second stage, each of the first stage and the second stage having a first surface and a second surface opposite the first surface, the first surface of the first stage of the multi-stage via being proximate the first side of the semiconductor structure, the first surface of the first stage of the multi-stage via being proximate the second side of the semiconductor structure, and the second surface of the first stage of the multi-stage via abutting the second surface of the second stage of the multi-stage via. The multi-stage via provides a signal connection between the first back-end-of-line structure and the second back-end-of-line structure. A first diameter of the first surface of the first stage of the multi-stage via is greater than or equal to a second diameter of the second surface of the second stage of the multi-stage via. A first diameter of the first surface of the second stage of the multi-stage via is greater than or equal to a second diameter of the second surface of the second stage of the multi-stage via. The multi-stage via advantageously provides lower resistance (e.g., relative to a single-stage via), with resulting improvements in device performance.

The second surface of the first stage of the multi-stage via may abut the second surface of the second stage of the multi-stage via proximate a midpoint between the first side of the semiconductor structure and the second side of the semiconductor structure.

In another embodiment, a method comprises forming a first stage of a multi-stage via in a semiconductor structure utilizing processing from a first side of the semiconductor structure, the first stage of the multi-stage via having a first surface and a second surface opposite the first surface. The method also comprises forming a second stage of the multi-stage via in the semiconductor structure utilizing processing from a second side of the semiconductor structure, the first stage of the multi-stage via having a first surface and a second surface opposite the first surface. The first surface of the first stage of the multi-stage via is proximate the first side of the semiconductor structure, the first surface of the second stage of the multi-stage via is proximate the second side of the semiconductor structure, and the second surface of the first stage of the multi-stage via abuts the second surface of the second stage of the multi-stage via. The multi-stage via advantageously provides lower resistance (e.g., relative to a single-stage via), with resulting improvements in device performance.

A first diameter of the first surface of the first stage of the multi-stage via may be greater than or equal to a second diameter of the second surface of the second stage of the multi-stage via, and a first diameter of the first surface of the second stage of the multi-stage via may be greater than or equal to a second diameter of the second surface of the second stage of the multi-stage via.

The second surface of the first stage of the multi-stage via may abut the second surface of the second stage of the multi-stage via proximate a midpoint between the first side of the semiconductor structure and the second side of the semiconductor structure.

### BRIEF DESCRIPTION OF THE DRAWINGS

FIG. 1A depicts a first cross-sectional view of a stacked nanosheet transistor structure with a multi-stage via for power connection, according to an embodiment of the invention.

FIG. 1B depicts a second cross-sectional view of the stacked nanosheet transistor structure with the multi-stage via for power connection, according to an embodiment of the invention.

FIG. 1C depicts a top-down view showing where the first and second cross-sectional views of FIGS. 1A and 1B are taken, according to an embodiment of the invention.

FIG. 2A depicts a first cross-sectional view of a stacked nanosheet transistor structure with a single-stage via for power connection, according to an embodiment of the invention.

FIG. 2B depicts a second cross-sectional view of the stacked nanosheet transistor structure with the single-stage via for power connection, according to an embodiment of the invention.

FIG. 2C depicts a top-down view showing where the first and second cross-sectional views of FIGS. 2A and 2B are taken, according to an embodiment of the invention.

FIG. 3A depicts a first cross-sectional view of a stacked nanosheet transistor structure with a multi-stage via for power connection and a multi-stage via for signal connection, according to an embodiment of the invention.

FIG. 3B depicts a second cross-sectional view of the stacked nanosheet transistor structure with the multi-stage via for power connection and the multi-stage via for signal connection, according to an embodiment of the invention.

FIG. 3C depicts a top-down view showing where the first and second cross-sectional views of FIGS. 3A and 3B are taken, according to an embodiment of the invention.

FIG. 4 depicts a cross-sectional view of a semiconductor structure including a substrate with an etch stop layer, according to an embodiment of the invention.

FIG. 5 depicts a cross-sectional view of the structure of FIG. 4 following formation of a nanosheet stack over the substrate, according to an embodiment of the invention.

FIG. 6A depicts a first cross-sectional view of the structure of FIG. 5 following patterning of the nanosheet stack for bottom and top nanosheet transistor structures, according to an embodiment of the invention.

FIG. 6B depicts a second cross-sectional view of the structure of FIG. 5 following the patterning of the nanosheet stack for the bottom and top nanosheet transistor structures, according to an embodiment of the invention.

FIG. 6C depicts a top-down view showing where the first and second cross-sectional views of FIGS. 6A and 6B are taken, according to an embodiment of the invention.

FIG. 7A depicts a first cross-sectional view of the structure of FIGS. 6A-6C following formation of dummy gate structures, according to an embodiment of the invention.

FIG. 7B depicts a second cross-sectional view of the structure of FIGS. 6A-6C following the formation of the dummy gate structures, according to an embodiment of the invention.

FIG. 7C depicts a top-down view showing where the first and second cross-sectional views of FIGS. 7A and 7B are taken, according to an embodiment of the invention.

FIG. 8A depicts a first cross-sectional view of the structure of FIGS. 7A-7C following removal of a middle dielectric isolation sacrificial layer from the nanosheet stack, according to an embodiment of the invention.

FIG. 8B depicts a second cross-sectional view of the structure of FIGS. 7A-7C following the removal of the sacrificial layer from the nanosheet stack, according to an embodiment of the invention.

FIG. 8C depicts a top-down view showing where the first and second cross-sectional views of FIGS. 8A and 8B are taken, according to an embodiment of the invention.

FIG. 9A depicts a first cross-sectional view of the structure of FIGS. 8A-8C following formation of a middle dielectric insulator layer, according to an embodiment of the invention.

FIG. 9B depicts a second cross-sectional view of the structure of FIGS. 8A-8C following the formation of the middle dielectric insulator layer, according to an embodiment of the invention.

FIG. 9C depicts a top-down view showing where the first and second cross-sectional views of FIGS. 9A and 9B are taken, according to an embodiment of the invention.

FIG. 10A depicts a first cross-sectional view of the structure of FIGS. 9A-9C following nanosheet recess and inner spacer formation, according to an embodiment of the invention.

FIG. 10B depicts a second cross-sectional view of the structure of FIGS. 9A-9C following the nanosheet recess and the inner spacer formation, according to an embodiment of the invention.

FIG. 10C depicts a top-down view showing where the first and second cross-sectional views of FIGS. 10A and 10B are taken, according to an embodiment of the invention.

FIG. 11A depicts a first cross-sectional view of the structure of FIGS. 10A-10C following formation of sacrificial placeholder layers, according to an embodiment of the invention.

FIG. 11B depicts a second cross-sectional view of the structure of FIGS. 10A-10C following the formation of the sacrificial placeholder layers, according to an embodiment of the invention.

FIG. 11C depicts a top-down view showing where the first and second cross-sectional views of FIGS. 11A and 11B are taken, according to an embodiment of the invention.

FIG. 12A depicts a first cross-sectional view of the structure of FIGS. 11A-11C following formation of source/drain regions, according to an embodiment of the invention.

FIG. 12B depicts a second cross-sectional view of the structure of FIGS. 11A-11C following the formation of the source/drain regions, according to an embodiment of the invention.

FIG. 12C depicts a top-down view showing where the first and second cross-sectional views of FIGS. 12A and 12B are taken, according to an embodiment of the invention.

FIG. 13A depicts a first cross-sectional view of the structure of FIGS. 12A-12C following replacement metal gate formation of gate structures for the bottom nanosheet transistor structures, according to an embodiment of the invention.

FIG. 13B depicts a second cross-sectional view of the structure of FIGS. 12A-12C following the replacement metal gate formation of gate structures for the bottom nanosheet transistor structures, according to an embodiment of the invention.

FIG. 13C depicts a top-down view showing where the first and second cross-sectional views of FIGS. 13A and 13B are taken, according to an embodiment of the invention.

FIG. 14A depicts a first cross-sectional view of the structure of FIGS. 13A-13C following replacement metal gate formation of the gate structures for the top nanosheet transistor structures, according to an embodiment of the invention.

FIG. 14B depicts a second cross-sectional view of the structure of FIGS. 13A-13C following the replacement metal gate formation of the gate structures for the top nanosheet transistor structures, according to an embodiment of the invention.

FIG. 14C depicts a top-down view showing where the first and second cross-sectional views of FIGS. 14A and 14B are taken, according to an embodiment of the invention.

FIG. 15A depicts a first cross-sectional view of the structure of FIGS. 14A-14C following gate cut patterning and dielectric fill, according to an embodiment of the invention.

FIG. 15B depicts a second cross-sectional view of the structure of FIGS. 14A-14C following the gate cut patterning and the dielectric fill, according to an embodiment of the invention.

FIG. 15C depicts a top-down view showing where the first and second cross-sectional views of FIGS. 15A and 15B are taken, according to an embodiment of the invention.

FIG. 16A depicts a first cross-sectional view of the structure of FIGS. 15A-15C following patterning of a first stage of a multi-stage via and fill of a sacrificial layer in the bottom portion of the first stage of the multi-stage via, according to an embodiment of the invention.

FIG. 16B depicts a second cross-sectional view of the structure of FIGS. 15A-15C following the patterning of the first stage of the multi-stage via and fill of the sacrificial layer in the bottom portion of the first stage of the multi-stage via, according to an embodiment of the invention.

FIG. 16C depicts a third cross-sectional view of the structure of FIGS. 15A-15C following the patterning of the first stage of the multi-stage via and fill of the sacrificial layer in the bottom portion of the first stage of the multi-stage via, according to an embodiment of the invention.

FIG. 16D depicts a top-down view showing where the first, second and third cross-sectional views of FIGS. 16A, 16B and 16C are taken, according to an embodiment of the invention.

FIG. 17A depicts a first cross-sectional view of the structure of FIGS. 16A-16D following patterning of openings for middle-of-line contacts to the gates and source/drain regions of the top nanosheet transistor structures and the first stage of the multi-stage via, according to an embodiment of the invention.

FIG. 17B depicts a second cross-sectional view of the structure of FIGS. 16A-16D following the patterning of the openings for the middle-of-line contacts to the gates and source/drain regions of the top nanosheet transistor structures and the first stage of the multi-stage via, according to an embodiment of the invention.

FIG. 17C depicts a third cross-sectional view of the structure of FIGS. 16A-16D following the patterning of the openings for the middle-of-line contacts to the gates and source/drain regions of the top nanosheet transistor structures and the first stage of the multi-stage via, according to an embodiment of the invention.

FIG. 17D depicts a top-down view showing where the first, second and third cross-sectional views of FIGS. 17A, 17B and 17C are taken, according to an embodiment of the invention.

FIG. 18A depicts a first cross-sectional view of the structure of FIGS. 17A-17D following metallization of the middle-of-line contacts to the gates and source/drain regions of the top nanosheet transistor structures and the first stage of the multi-stage via, according to an embodiment of the invention.

FIG. 18B depicts a second cross-sectional view of the structure of FIGS. 17A-17D following the metallization of the middle-of-line contacts to the gates and source/drain regions of the top nanosheet transistor structures and the first stage of the multi-stage via, according to an embodiment of the invention.

FIG. 18C depicts a third cross-sectional view of the structure of FIGS. 17A-17D following the metallization of the middle-of-line contacts to the gates and source/drain regions of the top nanosheet transistor structures and the first stage of the multi-stage via, according to an embodiment of the invention.

FIG. 18D depicts a top-down view showing where the first, second and third cross-sectional views of FIGS. 18A, 18B and 18C are taken, according to an embodiment of the invention.

FIG. 19A depicts a first cross-sectional view of the structure of FIGS. 18A-18D following frontside back-end-of-line formation and bonding to a carrier wafer, according to an embodiment of the invention.

FIG. 19B depicts a second cross-sectional view of the structure of FIGS. 18A-18D following the frontside back-end-of-line formation and the bonding to the carrier wafer, according to an embodiment of the invention.

FIG. 19C depicts a third cross-sectional view of the structure of FIGS. 18A-18D following the frontside back-end-of-line formation and the bonding to the carrier wafer, according to an embodiment of the invention.

FIG. 19D depicts a top-down view showing where the first, second and third cross-sectional views of FIGS. 19A, 19B and 19C are taken, according to an embodiment of the invention.

FIG. 20A depicts a first cross-sectional view of the structure of FIGS. 19A-19D following removal of the substrate from the backside and formation of a backside interlayer dielectric layer, according to an embodiment of the invention.

FIG. 20B depicts a second cross-sectional view of the structure of FIGS. 19A-19D following the removal of the substrate from the backside and the formation of the backside interlayer dielectric layer, according to an embodiment of the invention.

FIG. 20C depicts a third cross-sectional view of the structure of FIGS. 19A-19D following the removal of the substrate from the backside and the formation of the backside interlayer dielectric layer, according to an embodiment of the invention.

FIG. 20D depicts a top-down view showing where the first, second and third cross-sectional views of FIGS. 20A, 20B and 20C are taken, according to an embodiment of the invention.

FIG. 21A depicts a first cross-sectional view of the structure of FIGS. 20A-20D following removal of the sacrificial placeholder layer and the sacrificial layer from the bottom portion of the first stage of the multi-stage via followed by patterning of a second stage of the multi-stage via, according to an embodiment of the invention.

FIG. 21B depicts a second cross-sectional view of the structure of FIGS. 20A-20D following the removal of the sacrificial placeholder layer and the sacrificial layer from the bottom portion of the first stage of the multi-stage via followed by the patterning of the second stage of the multi-stage via, according to an embodiment of the invention.

FIG. 21C depicts a third cross-sectional view of the structure of FIGS. 20A-20D following the removal of the sacrificial placeholder layer and the sacrificial layer from the bottom portion of the first stage of the multi-stage via followed by the patterning of the second stage of the multi-stage via, according to an embodiment of the invention.

FIG. 21D depicts a top-down view showing where the first, second and third cross-sectional views of FIGS. 21A, 21B and 21C are taken, according to an embodiment of the invention.

FIG. 22A depicts a first cross-sectional view of the structure of FIGS. 21A-21D following formation of backside contacts and fill of the second stage of the multi-stage via, according to an embodiment of the invention.

FIG. 22B depicts a second cross-sectional view of the structure of FIGS. 21A-21D following the formation of the backside contacts and the fill of the second stage of the multi-stage via, according to an embodiment of the invention.

FIG. 22C depicts a third cross-sectional view of the structure of FIGS. 21A-21D following the formation of the backside contacts and the fill of the second stage of the multi-stage via, according to an embodiment of the invention.

FIG. 22D depicts a top-down view showing where the first, second and third cross-sectional views of FIGS. 22A, 22B and 22C are taken, according to an embodiment of the invention.

FIG. 23A depicts a first cross-sectional view of the structure of FIGS. 22A-22D following formation of a backside back-end-of-line structure, according to an embodiment of the invention.

FIG. 23B depicts a second cross-sectional view of the structure of FIGS. 22A-22D following the formation of the backside back-end-of-line structure, according to an embodiment of the invention.

FIG. 23C depicts a third cross-sectional view of the structure of FIGS. 22A-22D following the formation of the backside back-end-of-line structure, according to an embodiment of the invention.

FIG. 23D depicts a top-down view showing where the first, second and third cross-sectional views of FIGS. 23A, 23B and 23C are taken, according to an embodiment of the invention.

FIG. 24 shows an integrated circuit comprising a semiconductor structure with one or more multi-stage vias, according to an embodiment of the invention.

### DETAILED DESCRIPTION

Illustrative embodiments of the invention may be described herein in the context of illustrative methods for forming multi-stage vias, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

As discussed above, various techniques may be used to reduce the area of FETs, including through the use of fin-shaped channels in FinFET devices, through the use of stacked nanosheet channels formed over a semiconductor substrate, etc.

Increasing demand for high density and performance in integrated circuit devices requires development of new structural and design features, including shrinking gate lengths and other reductions in size or scaling of devices. Continued scaling, however, is reaching limits of conventional fabrication techniques.

Stacking transistors in a vertical direction gives an additional dimension for CMOS area scaling. There are various challenges, however, in forming stacked FET structures. One challenge, for example, is in wiring the “top” transistor devices to backside power. Another challenge is in sending signals or power from the backside to the frontside of a structure, or vice versa. Conventional approaches either lead to poor performance (e.g., when trying to use extremely small contacts to save area for scaling and parasitic capacitance) or larger cell size (e.g., when trying to make a robust contact size and contact spacing). For example, forming vias between the frontside and backside of stacked transistor structures presents various challenges. Such vias typically have a high aspect ratio (HAR), and are subject to patterning risk (e.g., due to HAR reactive-ion etch (RIE) processing and metal recess, etc.), high unit process risk (e.g., due to metal fill, dielectric fill, dielectric chemical mechanical planarization (CMP), interlayer dielectric (ILD) loss, etc.), and high process integration risk (e.g., due to a small bottom contact area, recess depth control, etc.). Conventional HAR vias are “single-stage” (e.g., formed by opening a trench from a frontside through to the backside of the structure, and then filling that trench). Such single-stage HAR vias include a bottom critical dimension (CD) that is significantly narrow than a top CD. The small bottom CD of single-stage HAR vias lead to higher resistance and significant performance concerns.

Illustrative embodiments provide techniques for forming multi-stage vias (e.g., multi-stage HAR vias). The multi-stage process include forming a first stage of the multi-stage via from the frontside of a structure, and forming a second stage of the multi-stage via from the backside of the structure. The formation of the multi-stage via (e.g., including the first stage formed by frontside processing and the second stage formed by backside processing) solves issues associated with high resistance resulting from small bottom CD area. For example, multi-stage vias can provide substantial resistance improvements (e.g., due to larger CD areas) which leads to performance improvements. The multi-stage via includes a first stage formed by frontside processing and a second stage formed by backside processing (e.g., such as for source/drain connection to backside VDD/VSS power, for passing signals between frontside and backside back-end-of-line (BEOL) structures, etc.). The multi-stage vias advantageously have lower patterning risk (e.g., by 50% or other splitting of the HAR RIE processing and metal recess), lower unit process risk (e.g., metal fill, dielectric fill, dielectric CMP, ILD loss, etc.), and lower process integration risk (e.g., since there is a larger bottom contact area in the multi-stage HAR via, less recess depth control, etc.).

A semiconductor structure may include one or more multi-stage vias formed using the techniques described herein. Such multi-stage vias may be HAR vias, where a first stage or portion of the multi-stage via is formed by frontside processing and a second stage or portion of the multi-stage via is formed by backside processing. In some embodiments, a source/drain region of a top or upper transistor structure (e.g., a top nanosheet FET of a vertically stacked nanosheet FET structure) is connected to a backside power rail (e.g., VDD/VSS) through a multi-stage via (e.g., with a first stage or portion formed by frontside processing and a second stage or portion formed by backside processing). In other embodiments, a multi-stage via is used for passing signaling between the frontside and backside of the semiconductor structure (e.g., between frontside and backside BEOL regions). In some embodiments, there is provided co-integration of a second stage or portion of a multi-stage via for a source/drain of a top or upper nanosheet FET in a stacked nanosheet transistor structure and direct backside contacts for source/drain regions of bottom or lower nanosheet FET in the stacked nanosheet transistor structure, using backside wafer processing in Backside Power Delivery Network (BSPDN) technology. In other embodiments, compatible integration processes are provided for other types of stacked structures, including stacked FET static random-access memory (SRAM) with vertically stacked transistor (e.g., nanosheet FET) structures in BSPDN technologies. It should be noted that multi-stage vias may also be used in non-stacked structures, such as non-stacked nanosheet FET structures. For example, a non-stacked nanosheet FET may have a large number of nanosheets (e.g., 10 or more), resulting in the need for formation of HAR vias between the front and backside of the structure including the non-stacked nanosheet FET. Various other examples are possible.

A process flow for forming a multi-stage via for stacked nanosheet transistor structures may include formation of a nanosheet stack (e.g., a Si/SiGe stack) and active region patterning, followed by dummy gate formation. Placeholder formation for direct backside contacts of bottom or lower nanosheet transistors is then performed, followed by source/drain epitaxial layer formation. Replacement metal gate (RMG) processing is then performed for the stacked nanosheet transistor structure. A gate cut process is then performed, followed by power via patterning and amorphous SiGe fill for the top or upper nanosheet transistors. Top power via metal fill and middle-of-line (MOL) processing is then performed, followed by frontside BEOL processing and bonding to a carrier wafer for backside processing. A wafer flip and substrate etching is then performed. The substrate etching may stop on an etch stop layer, followed by removal of the etch stop and remaining backside substrate etching. A backside interlayer dielectric (ILD) layer is then deposited, followed by the power via placeholder removal and retargeting. The direct backside contact placeholders are then removed, followed by backside metallization. A selective backside metal contact recess is then performed, followed by formation of an additional backside ILD layer and backside metallization.

The multi-stage vias described herein advantageously utilize backside processing for a second stage of multi-stage vias, which overcomes HAR via process challenges associated with single-stage RIE frontside processing. A device performance boost is provided, through a reduction of resistance relative to single-stage HAR vias. Advantageously, the processing described is compatible with direct backside contact and BSPDN technologies. Multi-stage vias may be used in various types of devices, such as logic devices, memory (e.g., SRAM) devices, etc., where it is desired to provide power or signal connections between top/upper devices and backside BEOL structures, or between frontside and backside of the structures (e.g., frontside and backside BEOL structures).

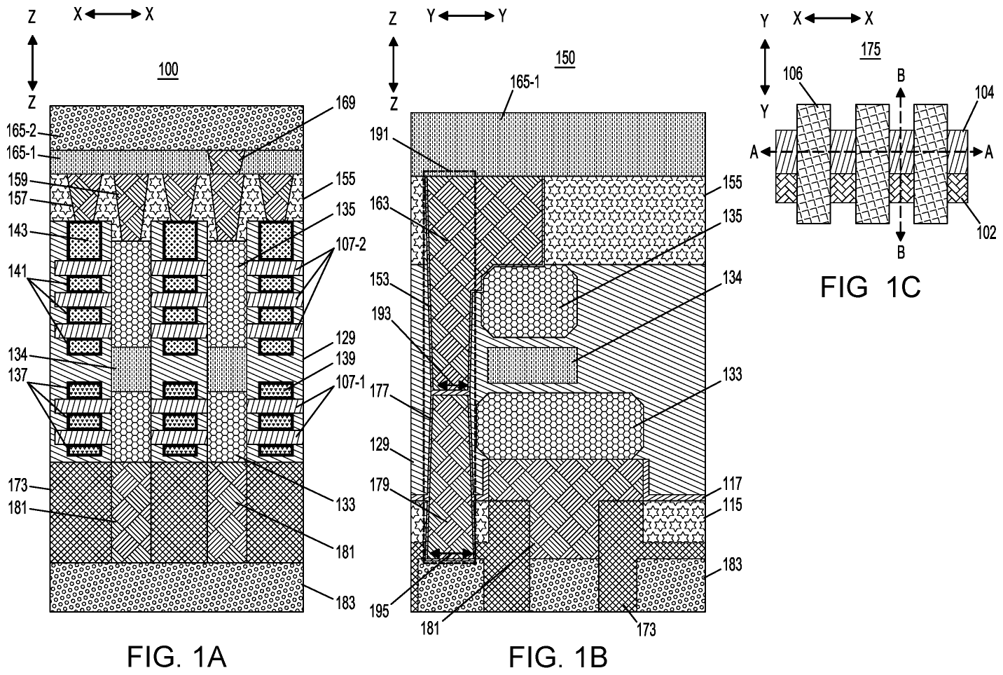

FIGS. 1A-1C show an example of a semiconductor structure including a multi-stage via 191. FIGS. 1A and 1B show respective first and second cross-sectional views 100 and 150 of a stacked nanosheet transistor structure including the multi-stage via 191, configured for power delivery. FIG. 1C shows a top-down view 175 illustrating where the cross-sectional views 100 of FIG. 1A and 150 of FIG. 1B are taken. The top-down view 175 shows an active region 102 for first (e.g., bottom/lower) nanosheet transistor structures, an active region 104 for second (e.g., top/upper) nanosheet transistor structures, and gate regions 106. The first cross-sectional view 100 of FIG. 1A is taken across the gate regions 106 along line A-A shown in the top-down view 175 of FIG. 1C, and the second cross-sectional view 150 of FIG. 1B is taken between two of the gate regions 104 along line B-B shown in the top-down view 175 of FIG. 1C.

The structure shown in FIGS. 1A and 1B includes: nanosheet channel layers 107-1 and 107-2, shallow trench isolation (STI) regions 115, nitride layer 117, middle dielectric insulator (MDI) layer and inner spacers 129, source/drain regions 133 and 135, isolator layer 134, gate dielectric layers 137, gate conductor layer 139, gate dielectric layers 141, gate conductor layer 143, multi-stage via first portion barrier layer 153, frontside ILD layer 155, middle-of-line contacts 157 and 159, multi-stage via first portion contact 163, frontside BEOL ILD layer 165-1, frontside BEOL metallization layer 165-2, frontside BEOL via 169, backside ILD layer 173, multi-stage via second portion barrier layer 177, backside contacts 181, multi-stage via second portion contact 179, and backside BEOL metallization layer 183. Details regarding these layers will be discussed in further detail below with respect to the process flow of FIGS. 5-24D, where like reference numerals denote similar elements.

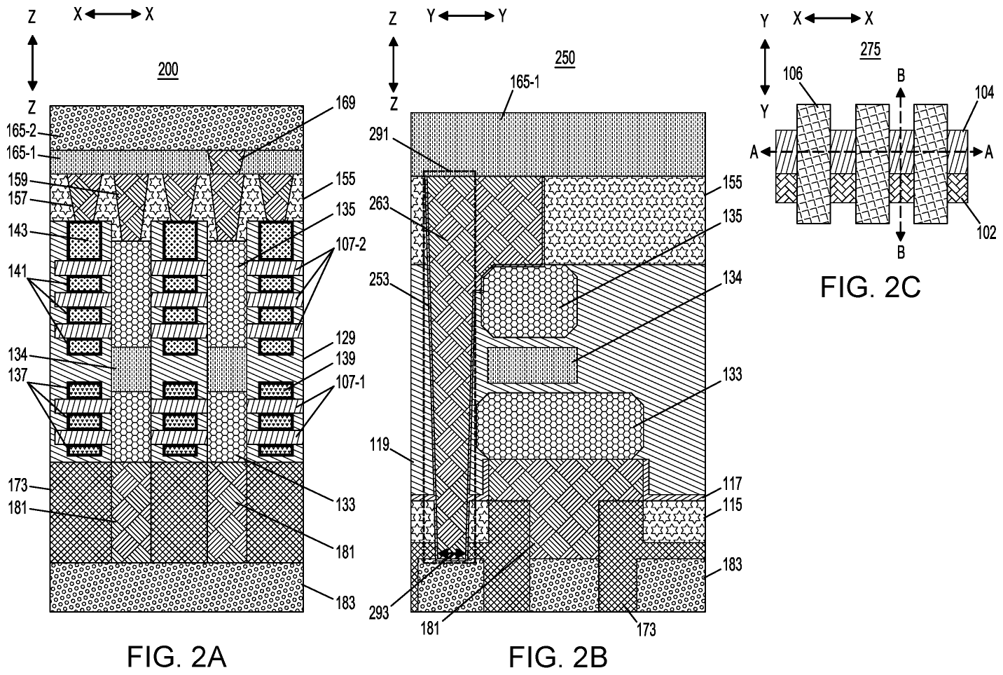

The multi-stage via 191 may be a “high aspect ratio” or HAR via. In some embodiments, a HAR via is one with an aspect ratio of 8:1-10:1 or greater. It should be appreciated, however, that multi-stage vias may be formed with other aspect ratios, including aspect ratios lower than 8:1. As shown in FIG. 1B, the multi-stage via 191 has a first stage or portion (e.g., filled with the multi-stage via first portion contact 163) with a bottom CD 193, and a second stage or portion (e.g., filled with the multi-stage via second portion contact 179) with a bottom CD 195. The bottom CD 195 is greater than the bottom CD 193. This is a result of the multi-step formation of the multi-stage via 191, where the first stage or portion is formed by frontside processing and the second stage or portion is formed by backside processing. Thus, advantageously, the bottom CD 195 which contacts the backside BEOL metallization layer 183 (e.g., VDD/VSS for power delivery to source/drain regions 135) has increased width relative to a single-stage via structure such as that shown in FIGS. 2A-2C.

FIGS. 2A-2C show an example of a semiconductor structure including a single-stage via 291. FIGS. 2A and 2B show respective first and second cross-sectional views 200 and 250 of a stacked nanosheet transistor structure including the single-stage via 291, configured for power delivery. FIG. 2C shows a top-down view 275 illustrating where the cross-sectional views 200 of FIG. 2A and 250 of FIG. 2B are taken. The top-down view 275 shows the active region 102 for the first (e.g., bottom/lower) nanosheet transistor structures, the active region 104 for the second (e.g., top/upper) nanosheet transistor structures, and the gate regions 106. The first cross-sectional view 200 of FIG. 2A is taken across the gate regions 106 along line A-A shown in the top-down view 275 of FIG. 2C, and the second cross-sectional view 250 of FIG. 2B is taken between two of the gate regions 104 along line B-B shown in the top-down view 275 of FIG. 2C.

The structure shown in FIGS. 2A and 2B includes many of the same elements as the structure of FIGS. 1A and 1B, with the exception of having the single-stage via 291 rather than the multi-stage via 191. The single-stage via 291 includes barrier layer 253, and contact 263. The single-stage via has a bottom CD 293, which is narrow than the bottom CD 193 of the multi-stage via 191, due to the fact that the single-stage via 291 would be formed with just frontside processing which must extend through to the backside of the structure.

Single-stage vias, such as those shown in FIGS. 2A and 2B, have a HAR via bottom CD critical risk, with a huge performance penalty due to the high resistance of the small bottom CD. Multi-stage vias overcome issues related to the small bottom CD of single-stage via structures, providing resistance improvement and performance improvement.

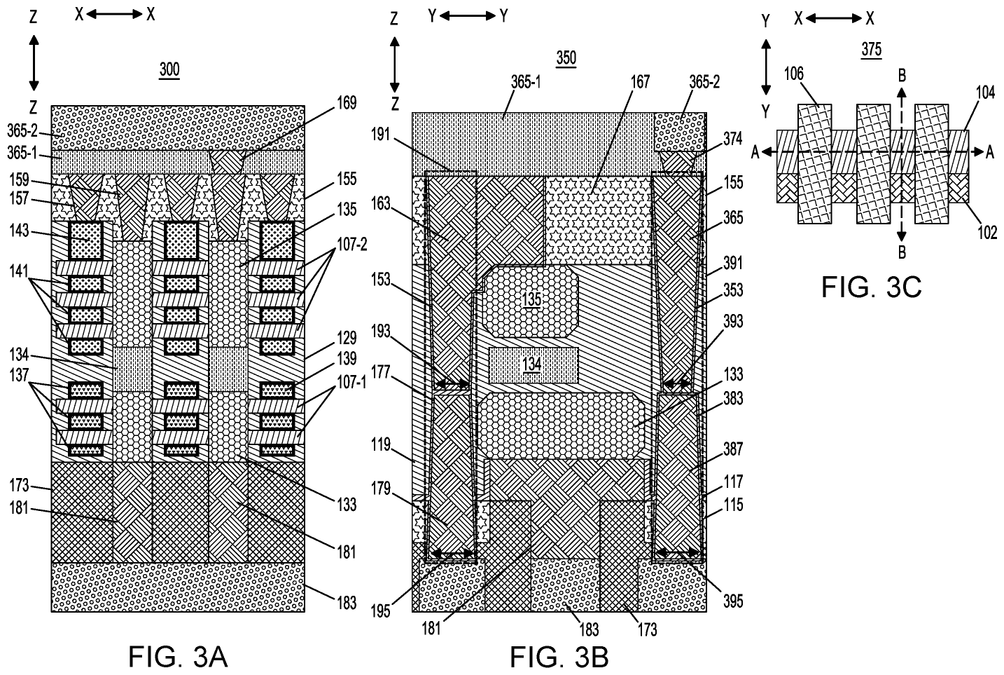

While FIGS. 1A-1C show a structure with just a single multi-stage via 191 for power delivery, embodiments are not limited to use with semiconductor structures having just one multi-stage via, or for using multi-stage vias for power delivery. FIGS. 3A-3C, for example, show a semiconductor structure with the multi-stage via 191 for power delivery to the source/drain regions 135 as well as another multi-stage via 391 for signal connection between the frontside and backside of the structure.

FIGS. 3A and 3B show respective first and second cross-sectional views 300 and 350 of a stacked nanosheet transistor structure including the multi-stage via 191 configured for power delivery and the multi-stage via 391 configured for signal connection. FIG. 3C shows a top-down view 375 illustrating where the cross-sectional views 300 of FIG. 3A and 350 of FIG. 3B are taken. The top-down view 375 shows the active region 102 for the first (e.g., bottom/lower) nanosheet transistor structures, the active region 104 for the second (e.g., top/upper) nanosheet transistor structures, and the gate regions 106. The first cross-sectional view 300 of FIG. 3A is taken across the gate regions 106 along line A-A shown in the top-down view 375 of FIG. 3C, and the second cross-sectional view 350 of FIG. 3B is taken between two of the gate regions 104 along line B-B shown in the top-down view 375 of FIG. 3C.

The structure shown in FIGS. 3A and 3B includes many of the same elements as the structure of FIGS. 1A and 1B, and further includes the multi-stage via 391. The multi-stage via 391 provides signal connection between the backside BEOL metallization layer 183 and frontside BEOL metallization layer 365-2, which is surrounded by frontside BEOL ILD layer 365-1. A frontside BEOL via 374 interconnects the frontside BEOL metallization layer 365-2 with the multi-stage via 391. The multi-stage via 391 includes a first stage or portion (e.g., formed by frontside processing) with a barrier layer 353 and contact 365, as well as a second stage or portion (e.g., formed by backside processing) with a barrier layer 383 and contact 387. The elements 353, 365, 383, 387 of the multi-stage via 391 are similar to the elements 153, 163, 177 and 179 of the multi-stage via 191.

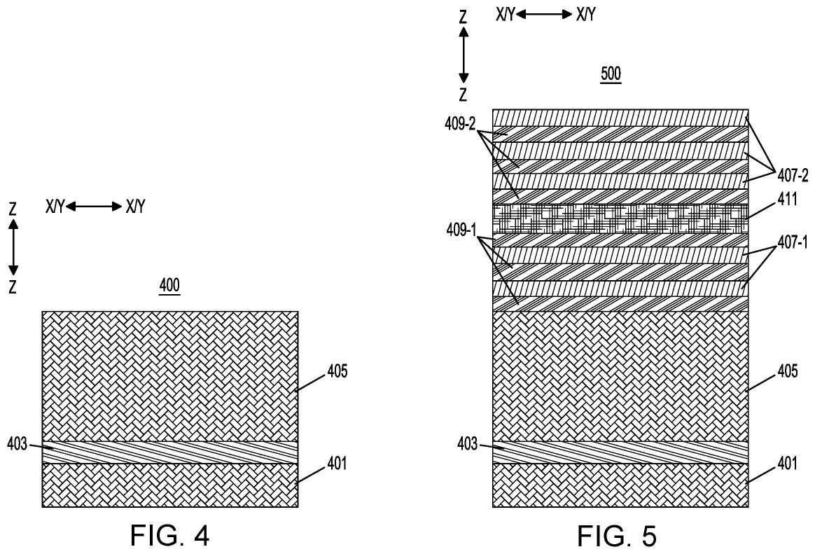

FIGS. 4-23D show a process flow for forming semiconductor structures with multi-stage vias. In the example of FIGS. 4-23D, the semiconductor structure includes a stacked nanosheet transistor structure. It should be appreciated, however, that embodiments are not limited to forming semiconductor structures with stacked nanosheet transistors. Multi-stage vias may be formed in various other types of semiconductor structures, including those which use other types of transistor structures (e.g., vertical transport field-effect transistors (VTFETs), stacked VTFETs, fin-type field-effect transistors (FinFETs), etc.). Multi-stage vias may also be formed in semiconductor structures including memory structures, logic gates, etc. While FIGS. 4-23D show an example where a multi-stage via is formed for a stacked structure, this is not a requirement. Multi-stage vias may also be formed for non-stacked structures.

FIG. 4 shows a cross-sectional view 400 of a semiconductor structure including a substrate including a first substrate portion 401 and a second substrate portion 405. An etch stop layer 503 is formed between the first substrate portion 401 and the second substrate portion 405.

The first substrate portion 401 and the second substrate portion 405 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. The first substrate portion 501 and the second substrate portion 505 may have respective heights (in direction Z) and widths (in directions X/Y) which vary as needed based on the type of structures to be formed.

The etch stop layer 403 may comprise a buried oxide (BOX) layer formed of silicon dioxide (SiO₂), silicon germanium (SiGe), or another suitable material such as a III-V semiconductor epitaxial layer. The etch stop layer 403 may have a height (in direction Z) in the range of 10 to 30 nm.

FIG. 5 shows a cross-sectional view 500 of the structure of FIG. 4 following formation of a nanosheet stack over the second substrate portion 405. The nanosheet stack includes a first portion having alternating nanosheet channel layers 407-1 and sacrificial layers 409-1, a sacrificial layer 411, and a second portion having alternating nanosheet channel layers 407-2 and sacrificial layers 409-2.

The nanosheet channel layers 407-1 will provide channels for first (e.g., bottom or lower) nanosheet transistor structures, while the nanosheet channel layers 407-2 will provide channels for second (e.g., top or upper) nanosheet transistor structures. The nanosheet channel layers 407-1 and 407-2 (collectively, nanosheet channel layers 407) may be formed of Si or another suitable material (e.g., a material similar to that used for the first substrate portion 401 and the second substrate portion 405). Each of the nanosheet channel layers 407 may have a thickness (in direction Z) in the range of 4-10 nm.

The sacrificial layers 409-1 and 409-2 (collectively, sacrificial layers 409) may be formed of a first sacrificial material and the sacrificial layer 411 may be formed of a second sacrificial material different than the first sacrificial material, such that the sacrificial layer 411 may be etched or otherwise removed selective to the sacrificial layers 409. In some embodiments, both the sacrificial layers 409 and the sacrificial layers 411 are formed of SiGe, but with different percentages of Ge. For example, the sacrificial layer 411 may have a relatively higher percentage of Ge (e.g., 55% Ge), and the sacrificial layers 409 may have a relatively lower percentage of Ge (e.g., 30% Ge). Other combinations of different sacrificial materials may be used in other embodiments. The sacrificial layers 409 and 411 may each have a thickness (in direction Z) in the range of 6-15 nm.

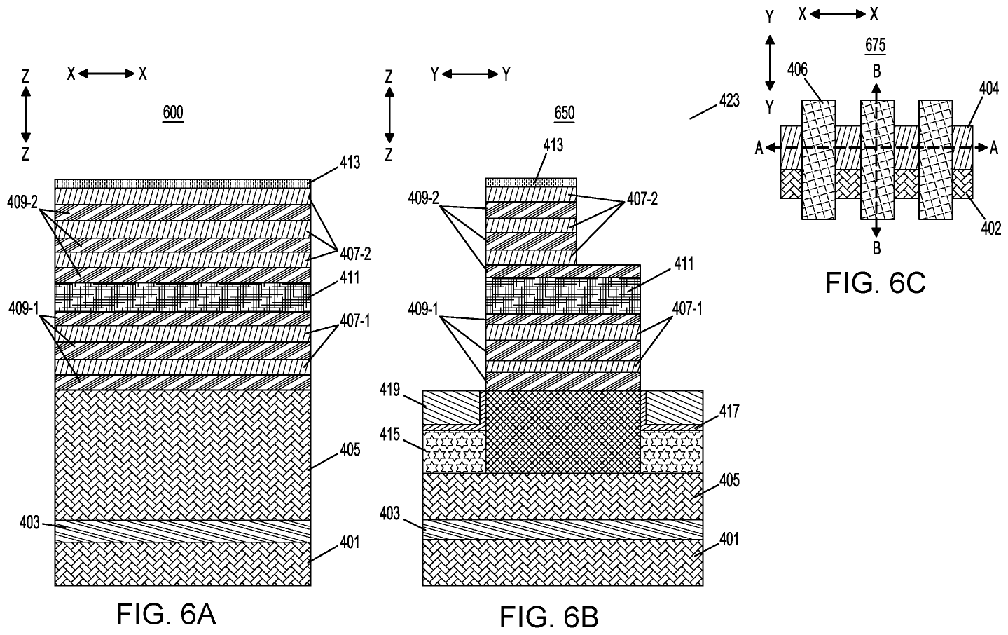

FIGS. 6A and 6B show respective first and second cross-sectional views 600 and 650 of the structure of FIG. 5, following patterning of the nanosheet stack for the first (e.g., bottom/lower) and second (e.g., top/upper) nanosheet transistor structures. FIG. 6C shows a top-down view 675, illustrating where the cross-sectional views 600 of FIG. 6A and 650 of FIG. 6B are taken. The top-down view 675 shows active region 402 for the first (e.g., bottom/lower) nanosheet transistor structures, active region 404 for the second (e.g., top/upper) nanosheet transistor structures, and gate regions 406. The first cross-sectional view 600 of FIG. 6A is taken across the gate regions 406 along line A-A shown in the top-down view 675 of FIG. 6C, and the second cross-sectional view 650 of FIG. 6B is taken along one of the gate regions 406 along line B-B shown in the top-down view 675 of FIG. 6C.

As shown in FIGS. 6A and 6B, a mask layer 413 is patterned over the nanosheet stack, followed by etching of the exposed portions of the nanosheet stack as well as the second substrate portion 405. This results in the sacrificial layer 411 as well as the nanosheet channel layers 407-1 and the sacrificial layers 409-1 being wider (in direction Y) than the nanosheet channel layers 407-2 and the sacrificial layers 409-2. For example, the width of the nanosheet channel layers 407-2 and the sacrificial layers 409-2 may be about half that of the sacrificial layer 411, the nanosheet channel layers 407-1 and the sacrificial layers 409-1.

Shallow trench isolation (STI) regions 415 are formed, along with a nitride liner 417 and an oxide layer 419. The STI regions 415 may be formed by patterning the mask layer 413 over the nanosheet stack, and then etching the exposed portions of the nanosheet stack and into the second substrate portion 405, followed by deposition or other formation of material for the STI regions 415. The STI regions 415 may be formed of a dielectric material such as silicon dioxide (SiO₂), silicon oxycarbide (SiOC), silicon oxynitride (SiON), etc. The STI regions 415 may have a height (in direction Z) in the range of 20 to 100 nm.

The nitride liner 417 may be formed using conformal atomic layer processing. The nitride liner 517 may be formed of silicon nitride (SiN) or another suitable material such as Silicon Carbon Nitride (SiCN) or another lower-k dielectric film. The nitride liner 417 may have a uniform thickness in the range of 2-4 nm.

The oxide layer 419 may be formed using flowable gap fill chemical vapor deposition (CVD), spin-on dielectric with bottom-up gap fill capabilities, etc. The oxide layer 519 may be formed of SiO, SiO₂ or another suitable material such as a spin-on dielectric, a lower-k gap fill film, etc. The oxide layer 419 may have a thickness (in direction Z) in the range of 10-50 nm.

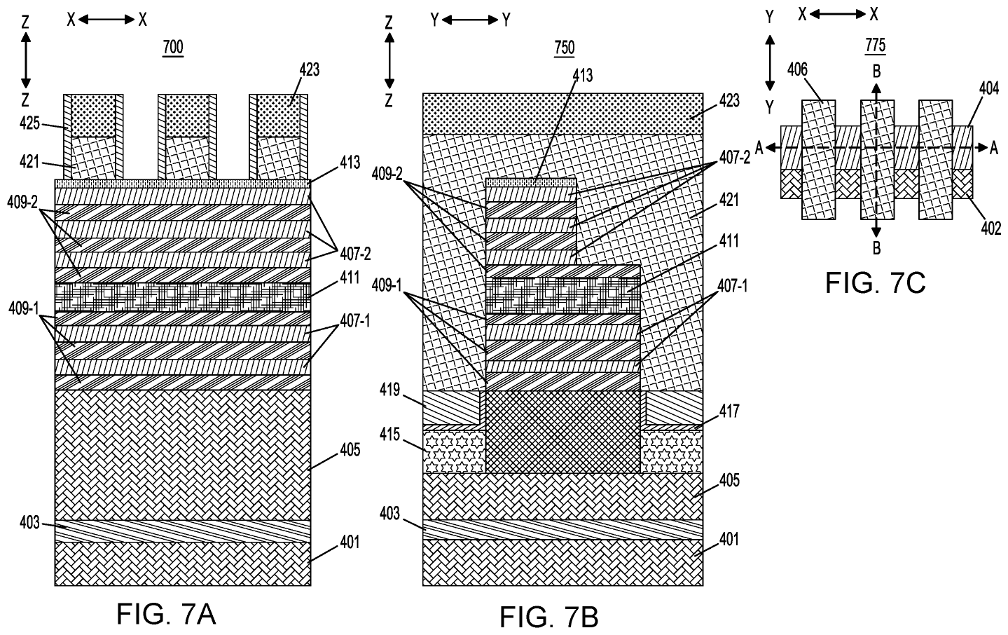

FIGS. 7A and 7B show respective first and second cross-sectional views 700 and 750 of the structure of FIGS. 6A-6C, following formation of dummy gate structures. FIG. 7C shows a top-down view 775, illustrating where the cross-sectional views 700 of FIG. 7A and 750 of FIG. 7B are taken. The first cross-sectional view 700 of FIG. 7A is taken across the gate regions 406 along line A-A shown in the top-down view 775 of FIG. 7C, and the second cross-sectional view 750 of FIG. 7B is taken along one of the gate regions 406 along line B-B shown in the top-down view 775 of FIG. 7C.

The dummy gate structure includes dummy gate layers 421, over which a gate hard mask (HM) layer 423 is patterned. Spacer layers 425 are formed on sidewalls of the dummy gate layers 421 and the gate HM layer 423. Material for the dummy gate layers 421 (e.g., amorphous silicon (a-Si) or amorphous silicon germanium (a-SiGe) over a thin SiO₂ or titanium nitride (TiN) layer, or another suitable material) may be blanket deposited over the structure, followed by formation and patterning of the gate HM layer 423 (e.g., formed of silicon nitride (SiN), a multi-layer of SiN and SiO₂, or another suitable material), followed by lithographic processing to result in the patterned dummy gate layers 421 and gate HM layer 423 as shown in FIGS. 7A and 7B. The spacer layer 425 may be formed using suitable deposition processing. The spacer layer 425 may be formed of a lower-k conformal dielectric film such as silicon boron carbon nitride (SiBCN), silicon oxygen carbon nitride (SiOCN), silicon oxygen carbide (SiOC), silicon oxygen carbon nitride (SiOCN), etc. The dummy gate layers 421 may each have a width (in direction X) in the range of 10-100 nm. The gate HM layer 423 may have a height (in direction Z) in the range of 10 nm or larger, and a width (in direction X) that matches that of the underlying dummy gate layers 421. The spacer layer 425 may have a width (in direction X) in the range of 5-10 nm.

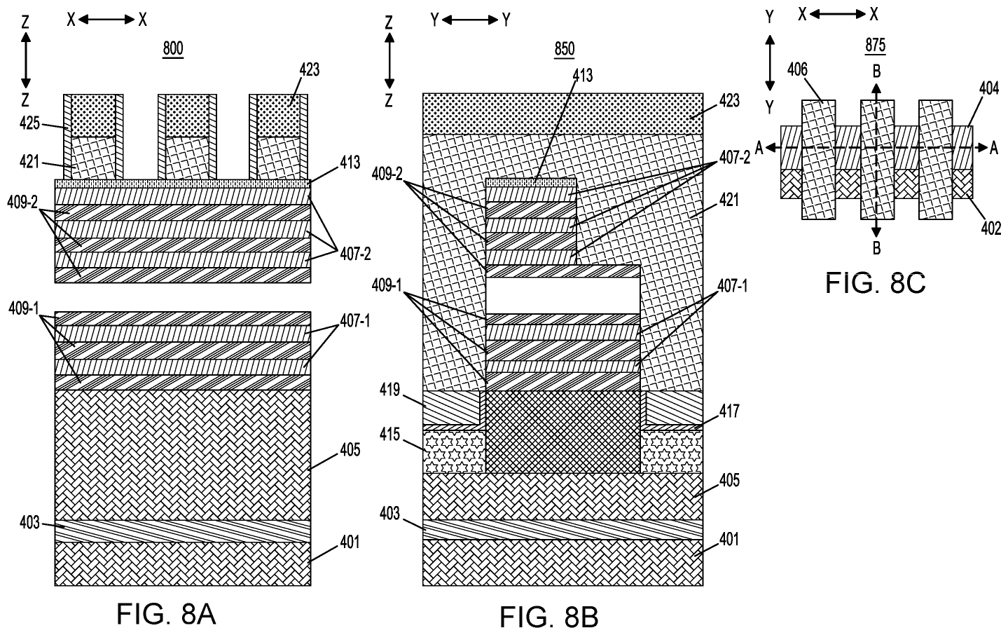

FIGS. 8A and 8B show respective first and second cross-sectional views 800 and 850 of the structure of FIGS. 7A-7C, following removal of the sacrificial layer 411 from the nanosheet stack. FIG. 8C shows a top-down view 875, illustrating where the cross-sectional views 800 of FIG. 8A and 850 of FIG. 8B are taken. The first cross-sectional view 800 of FIG. 8A is taken across the gate regions 406 along line A-A shown in the top-down view 875 of FIG. 8C, and the second cross-sectional view 850 of FIG. 8B is taken along one of the gate regions 406 along line B-B shown in the top-down view 875 of FIG. 8C.

The sacrificial layer 411 may be removed using any suitable etch processing which removes the material of the sacrificial layer 411 selective to that of the sacrificial layers 409 and the nanosheet channel layers 407.

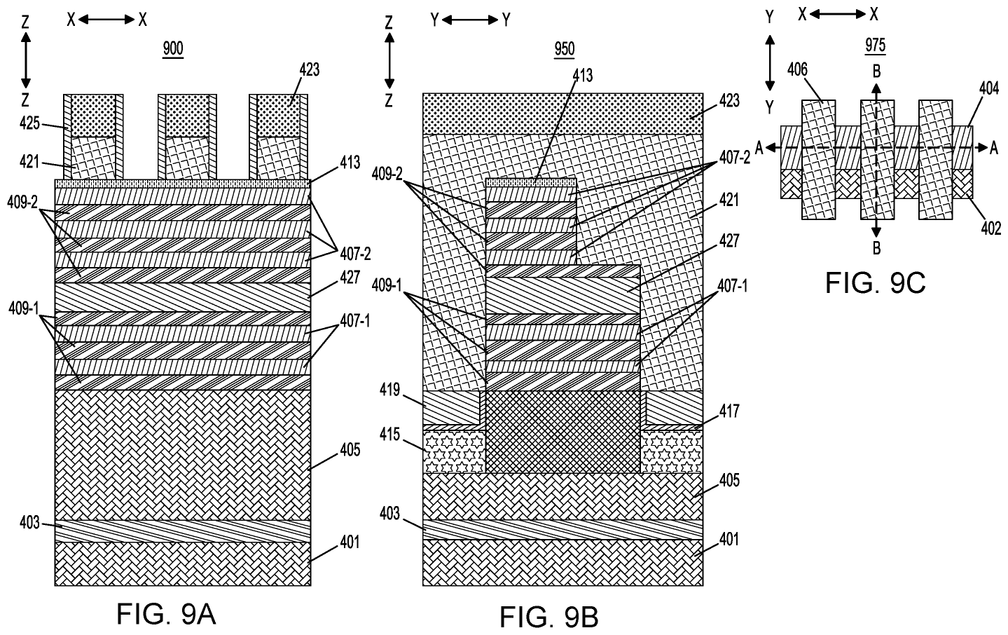

FIGS. 9A and 9B show respective first and second cross-sectional views 900 and 950 of the structure of FIGS. 8A-8C, following formation of a middle dielectric insulator (MDI) layer 427 in the space exposed by removal of the sacrificial layer 411. FIG. 9C shows a top-down view 975, illustrating where the cross-sectional views 900 of FIG. 9A and 950 of FIG. 9B are taken. The first cross-sectional view 900 of FIG. 9A is taken across the gate regions 406 along line A-A shown in the top-down view 975 of FIG. 9C, and the second cross-sectional view 950 of FIG. 9B is taken along one of the gate regions 406 along line B-B shown in the top-down view 975 of FIG. 9C.

The MDI layer 427 is formed in the space exposed by removal of the sacrificial layer 411, using isotropic deposition processing, conformal deposition processing, etc. The MDI layer 427 may be formed of any suitable insulator, such as SiN, silicon boron carbide nitride (SiBCN), silicon oxycarbonitride (SiOCN), etc.

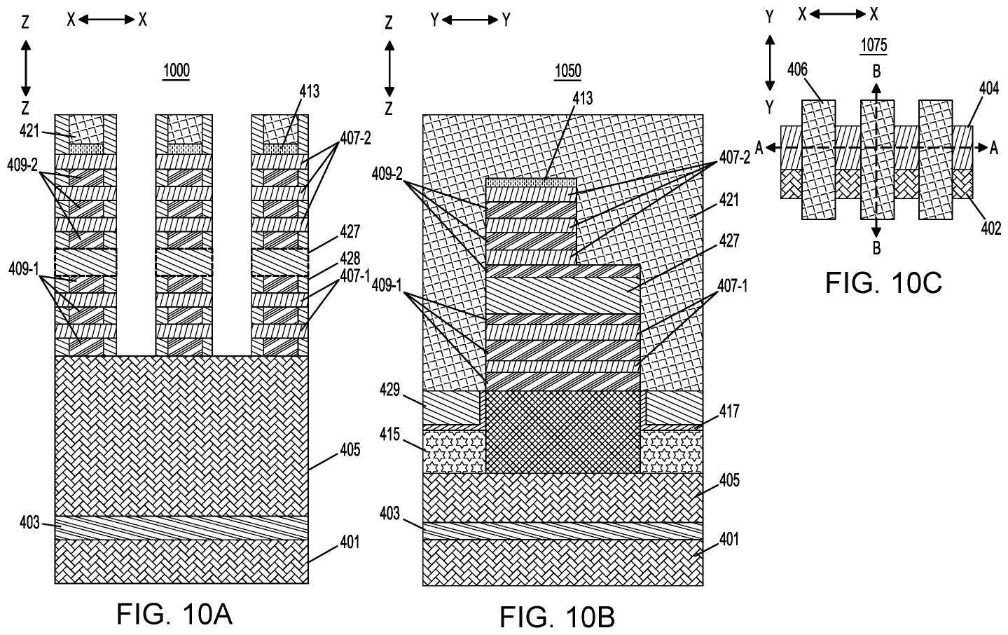

FIGS. 10A and 10B show respective first and second cross-sectional views 1000 and 1050 of the structure of FIGS. 9A-9C, following nanosheet recess and formation of inner spacers 428. FIG. 10C shows a top-down view 1075, illustrating where the cross-sectional views 1000 of FIG. 10A and 1050 of FIG. 10B are taken. The first cross-sectional view 1000 of FIG. 10A is taken across the gate regions 406 along line A-A shown in the top-down view 1075 of FIG. 10C, and the second cross-sectional view 1050 of FIG. 10B is taken along one of the gate regions 406 along line B-B shown in the top-down view 1075 of FIG. 10C.

The nanosheet recess of the nanosheet stack may be performed utilizing RIE or other suitable processing which removes the portions of the nanosheet stack which are exposed by the gate HM layer 423. An indent etch may then be performed to indent the sacrificial layers 409. The depth of the indent etch (in direction X) may be in the range of 5-9 nm. Spacer material for the inner spacers 428 is then formed and patterned. This spacer material may be the same as that of the MDI layer 427 (which is shown in dashed outline in FIG. 10A). In subsequent figures, the MDI layer 427 and inner spacers 428 are collectively denoted as element 429. The gate HM layer 423 is also removed following patterning of the spacer material for the inner spacers 428.

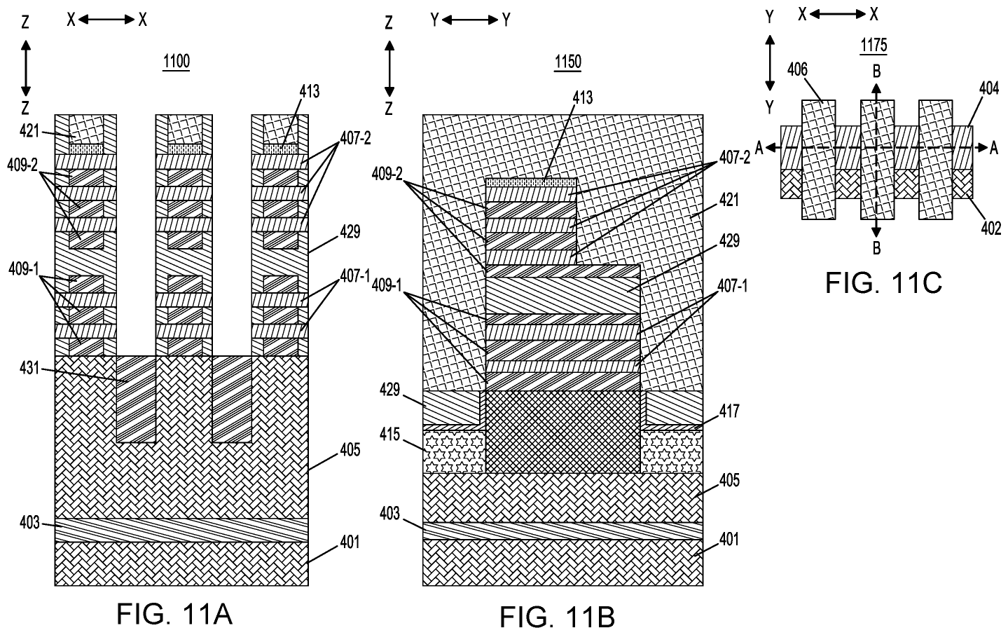

FIGS. 11A and 11B show respective first and second cross-sectional views 1100 and 1150 of the structure of FIGS. 10A-10C, following formation of sacrificial placeholder layers 431 in the second substrate portion 405. FIG. 11C shows a top-down view 1175, illustrating where the cross-sectional views 1100 of FIG. 11A and 1150 of FIG. 11B are taken. The first cross-sectional view 1100 of FIG. 11A is taken across the gate regions 406 along line A-A shown in the top-down view 1175 of FIG. 11C, and the second cross-sectional view 1150 of FIG. 11B is taken along one of the gate regions 406 along line B-B shown in the top-down view 1175 of FIG. 11C.

The sacrificial placeholder layers 431 may be formed by etching through the second substrate portion 405 to a predetermined depth, followed by deposition of a sacrificial placeholder material such as SiGe. The sacrificial placeholder layers 431 may have a height (in direction Z) in the range of 10-100 nm. The sacrificial placeholder layers 431 facilitate later formation of direct backside contacts, as will be discussed in further detail below.

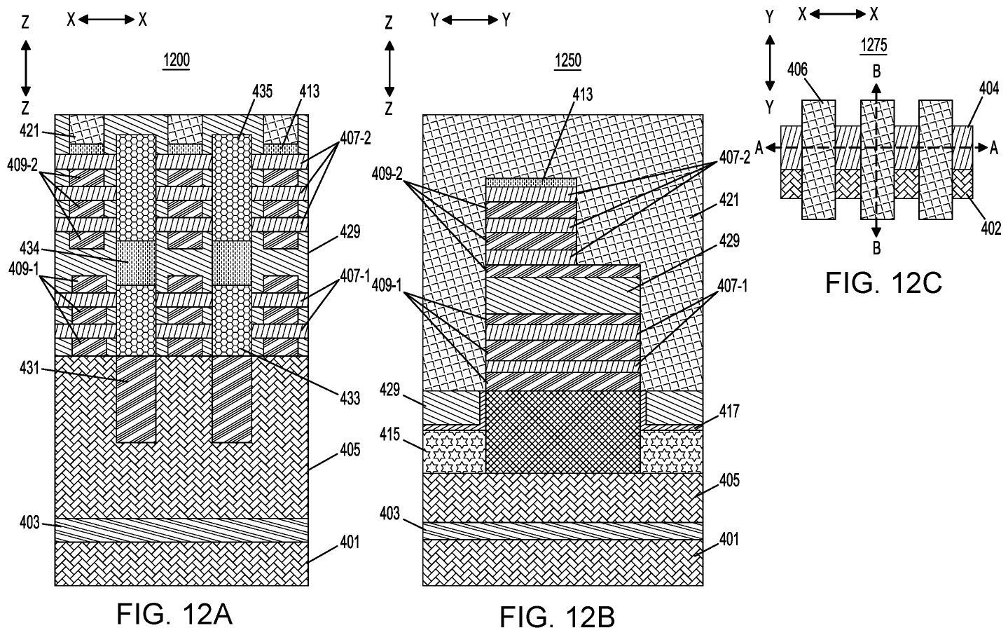

FIGS. 12A and 12B show respective first and second cross-sectional views 1200 and 1250 of the structure of FIGS. 11A-11C, following formation of source/drain regions 433, an isolation layer 434, and source/drain regions 435. FIG. 12C shows a top-down view 1275, illustrating where the cross-sectional views 1200 of FIG. 12A and 1250 of FIG. 12B are taken. The first cross-sectional view 1200 of FIG. 12A is taken across the gate regions 406 along line A-A shown in the top-down view 1275 of FIG. 12C, and the second cross-sectional view 1250 of FIG. 12B is taken along one of the gate regions 406 along line B-B shown in the top-down view 1275 of FIG. 12C.

The source/drain regions 433 are formed over the sacrificial placeholder layers 431 and below the MDI layer 427, between the nanosheet channel layers 407-1 for the first (e.g., bottom/lower) nanosheet transistor structures. The isolation layer 434, which may be formed of a nitride or other type of insulating material, is then formed over the source/drain regions 433. The source/drain regions 435 are formed over the isolation layer 434, between the nanosheet channel layers 407-2 for the second (e.g., top/upper) nanosheet transistor structures.

The source/drain regions 433 and 435 may be formed using an epitaxial growth process. The source/drain regions 433 and 435 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI). The source/drain regions 433 and 435 may be formed by an epitaxial growth process. In some embodiments, the epitaxy process comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³.

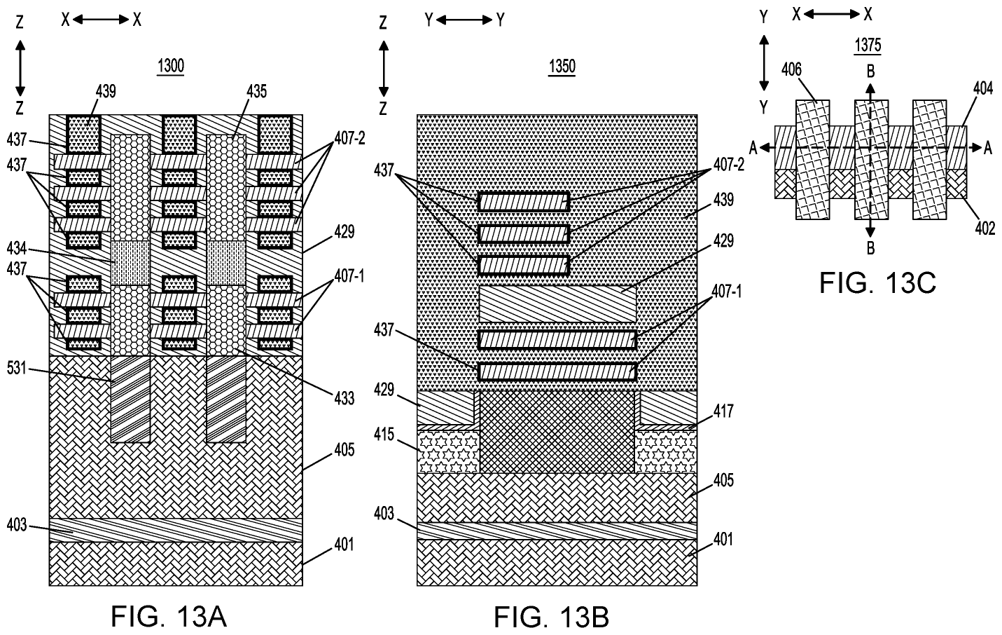

FIGS. 13A and 13B show respective first and second cross-sectional views 1300 and 1350 of the structure of FIGS. 12A-12C, following replacement metal gate (RMG) formation of gate structures for the first (e.g., bottom/lower) nanosheet transistor structures. FIG. 13C shows a top-down view 1375, illustrating where the cross-sectional views 1300 of FIG. 13A and 1350 of FIG. 13B are taken. The first cross-sectional view 1300 of FIG. 13A is taken across the gate regions 406 along line A-A shown in the top-down view 1375 of FIG. 13C, and the second cross-sectional view 1350 of FIG. 13B is taken along one of the gate regions 406 along line B-B shown in the top-down view 1375 of FIG. 13C.

RMG processing is used to form the gate structures for the first (e.g., bottom/lower) nanosheet transistor structures. The gate structures include gate dielectric layers 437 surrounding the nanosheet channel layers 407, and a gate conductor layer 439 surrounding the gate dielectric layers 439. The gate dielectric layers 437 may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layers 437 may have a uniform thickness in the range of 1 nm to 3 nm.

The gate conductor layer 439 may include a metal gate or work function metal (WFM). The WFM for the gate conductor layer 439 may be titanium (Ti), titanium nitride (TiN), tantalum (Ta), tantalum nitride (TaN), aluminum (Al), titanium aluminum (TiAl), titanium aluminum carbon (TiAIC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer 439 as desired.

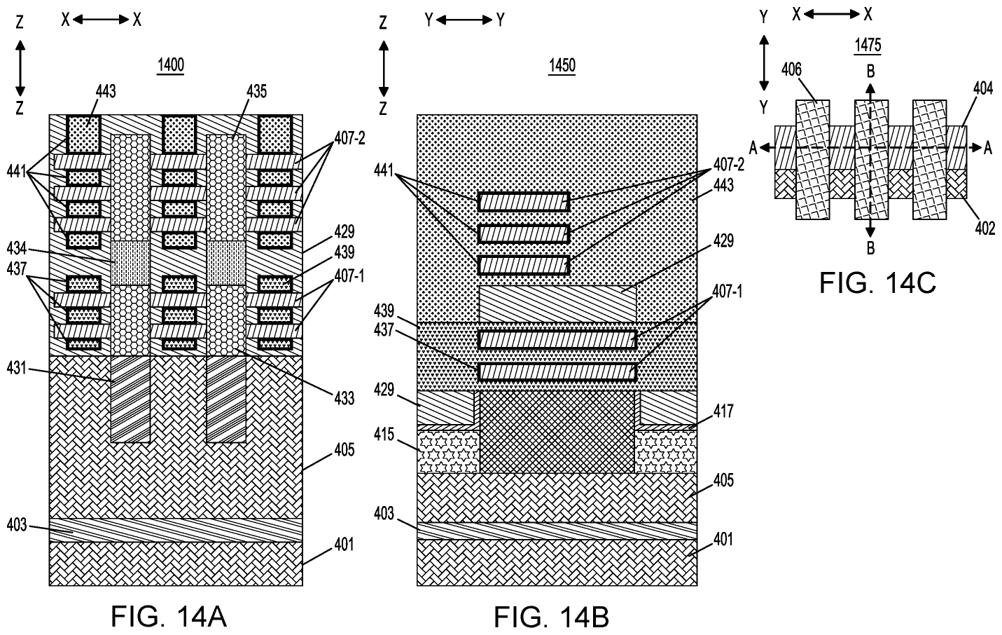

FIGS. 14A and 14B show respective first and second cross-sectional views 1400 and 1450 of the structure of FIGS. 13A-13C, following RMG formation of gate structures for the second (e.g., top/upper) nanosheet transistor structures. FIG. 14C shows a top-down view 1475, illustrating where the cross-sectional views 1400 of FIG. 14A and 1450 of FIG. 14B are taken. The first cross-sectional view 1400 of FIG. 14A is taken across the gate regions 406 along line A-A shown in the top-down view 1475 of FIG. 14C, and the second cross-sectional view 1450 of FIG. 14B is taken along one of the gate regions 406 along line B-B shown in the top-down view 1475 of FIG. 14C.

Prior to forming the gate structures for the second (e.g., top/upper) nanosheet transistor structures, the gate conductor layer 439 and gate dielectric layers 437 are recessed or removed by etching down to the MDI layer 427 (denoted collectively with the inner spacers 428 as element 429). It should be noted, in some cases, that the gate dielectric layers 437 need not be removed, as the same material may be used for the gate dielectric layers of gate structures for the second (e.g., top/upper) nanosheet transistor structures. RMG processing is then used to form the gate structures for the second (e.g., top/upper) nanosheet transistor structures. The gate structures include gate dielectric layers 441 surrounding the nanosheet channel layers 407-2, and a gate conductor layer 443 surrounding the gate dielectric layers 441. The gate dielectric layers 441 and gate conductor layer 443 may be formed of similar materials as the gate dielectric layers 437 and gate conductor layer 439.

In some embodiments, the gate conductor layer 439 comprises an n-type WFM material with the first (e.g., bottom/lower) nanosheet transistor structures comprising n-type nanosheet transistors and the gate conductor layer 443 comprises a p-type WFM material with the second (e.g., top/upper) nanosheet transistor structures comprising p-type nanosheet transistors. In other embodiments, this may be reversed, or both the first (e.g., bottom/lower) and second (e.g., top/upper) nanosheet transistor structures may be of the same type. If the same type is used for both the first and second nanosheet transistor structures, only one RMG processing step (e.g., that shown in FIGS. 13A-13C) is needed).

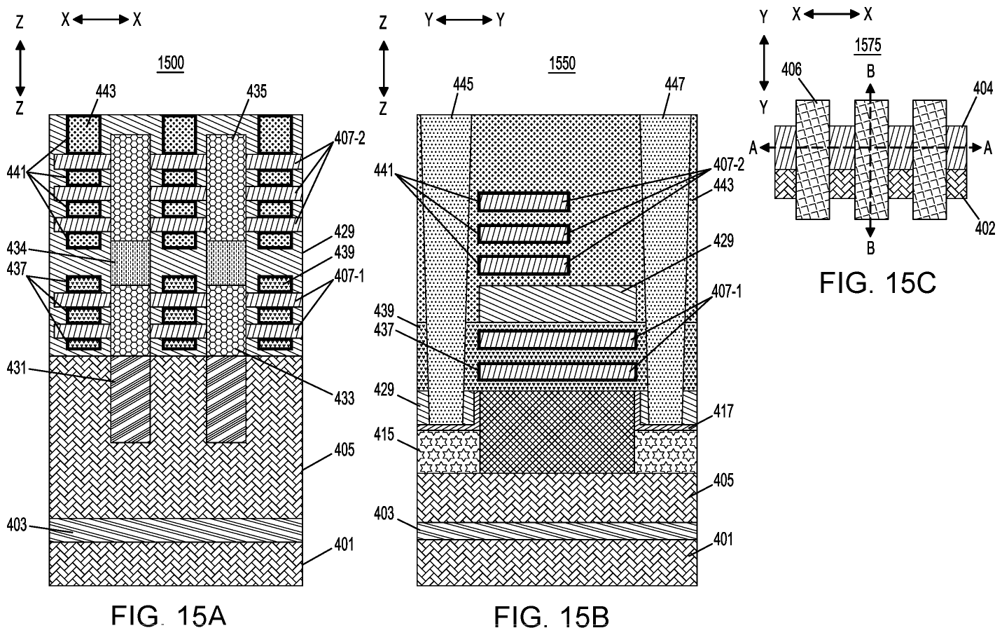

FIGS. 15A and 15B show respective first and second cross-sectional views 1500 and 1550 of the structure of FIGS. 14A-14C, following gate cut patterning and formation of gate cut trenches 445 and 447, which are filled with the dielectric material. FIG. 15C shows a top-down view 1675, illustrating where the cross-sectional views 1500 of FIG. 15A and 1550 of FIG. 15B are taken. The first cross-sectional view 1500 of FIG. 15A is taken across the gate regions 406 along line A-A shown in the top-down view 1575 of FIG. 15C, and the second cross-sectional view 1550 of FIG. 15B is taken along one of the gate regions 406 along line B-B shown in the top-down view 1575 of FIG. 15C.

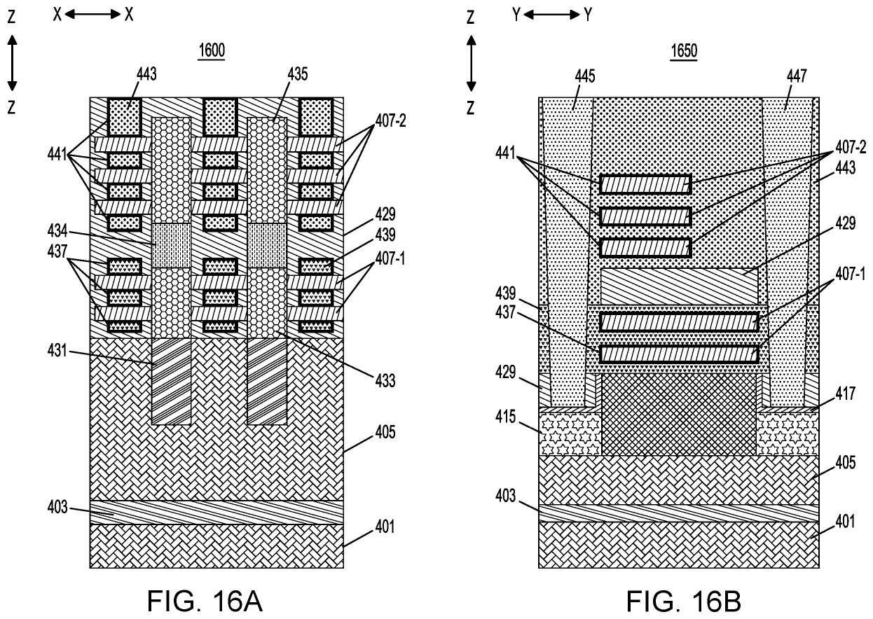

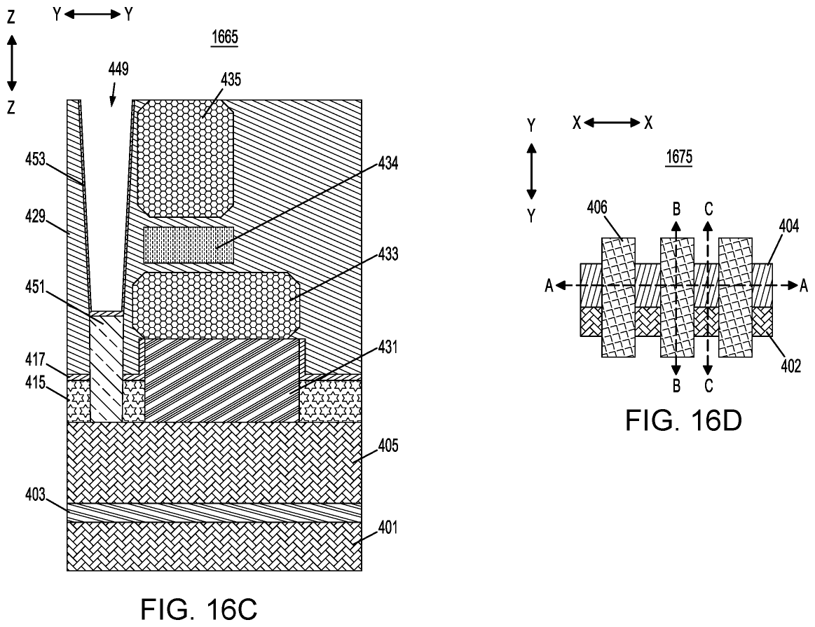

The gate cut patterning includes patterning a mask layer over the structure, with openings in areas where the gate cut trenches 445 and 447 are to be formed. The gate cut trenches 445 and 447 are then formed by etching through the gate conductor layers 439 and 443 as shown in FIG. 16B. The gate cut trenches 445 and 447 are then filled with a suitable dielectric material. The gate cut trenches 445 and 447 may have widths (in direction Y) in the range of 15-20 nm.

FIGS. 16A, 16B and 16C show respective first, second and third cross-sectional views 1600, 1650 and 1665 of the structure of FIGS. 15A-15C, following patterning of a first stage 449 of a multi-stage via and fill of a sacrificial layer 451 in a bottom portion of the first stage 449 of the multi-stage via. A barrier layer 453 is formed on sidewalls and bottom of the first stage 449 of the multi-stage via. FIG. 16D shows a top-down view 1675, illustrating where the cross-sectional views 1600 of FIG. 16A, 1650 of FIG. 16B and 1665 of FIG. 16C are taken. The first cross-sectional view 1600 of FIG. 16A is taken across the gate regions 406 along line A-A shown in the top-down view 1675 of FIG. 16D, the second cross-sectional view 1650 of FIG. 16B is taken along one of the gate regions 406 along line B-B shown in the top-down view 1675 of FIG. 16D, and the third cross-sectional view 1665 of FIG. 16C is taken between two of the gate regions 406 along line C-C shown in the top-down view 1675 of FIG. 16D.

The first stage 449 of the multi-stage via is formed by patterning a mask layer over the structure, and then etching through a portion of the inner spacers 428/MDI layer 427 (collectively denoted as element 429), the nitride liner 417 and the STI region 415 to one side of the source/drain regions 433 and 435. The first stage 449 of the multi-stage via is formed all the way through from the “frontside” to the “backside” of the structure. The sacrificial layer 451 is filled in the bottom portion of the first stage 449 of the multi-stage via (e.g., proximate the backside of the structure), about halfway through the total depth of the first stage 449 of the multi-stage via, though this may vary as desired. The barrier layer 453 is then formed on the sidewalls and bottom of the first stage 449 of the multi-stage via.

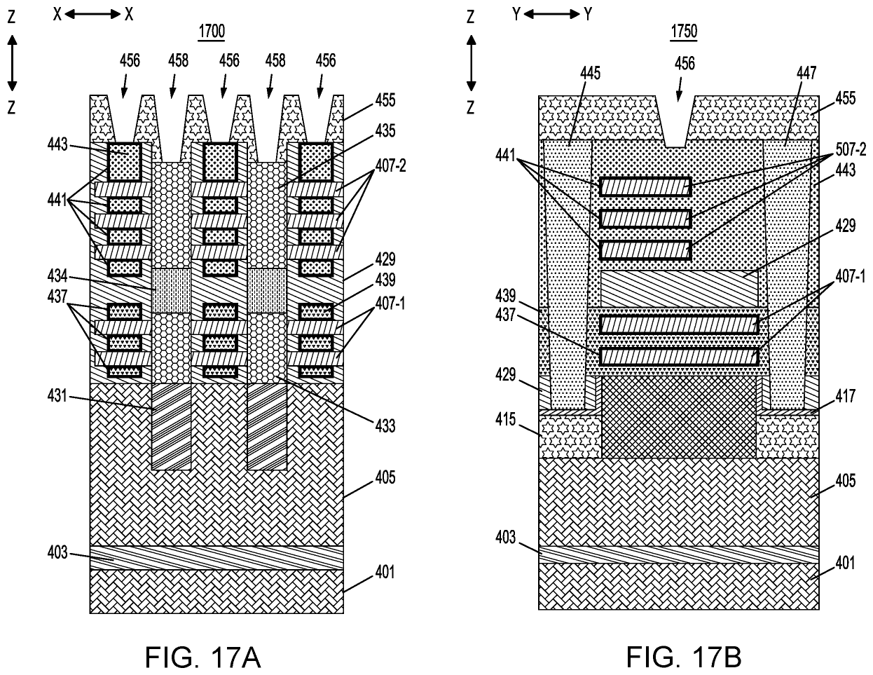

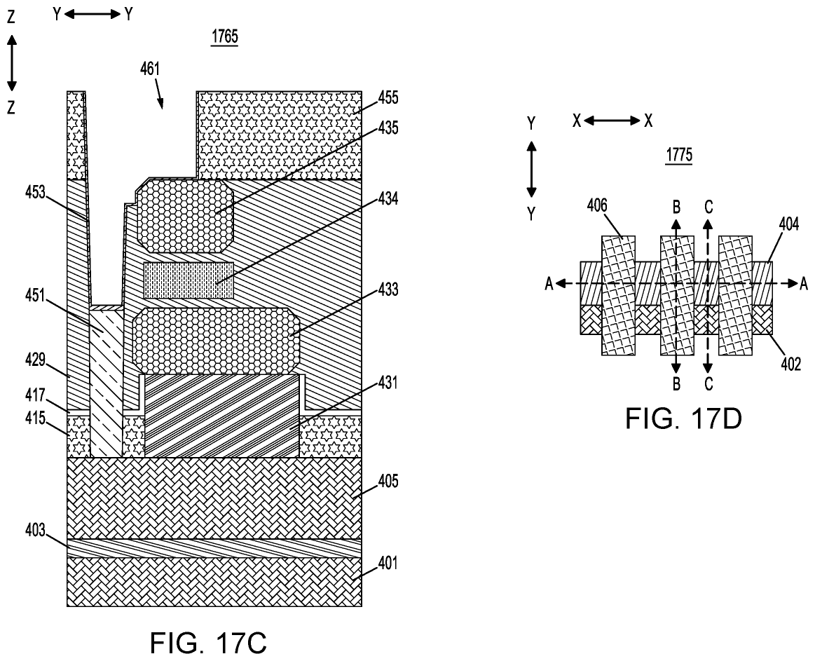

FIGS. 17A, 17B and 17C show respective first, second and third cross-sectional views 1700, 1750 and 1765 of the structure of FIGS. 16A-16D, following patterning of openings 456, 458 and 461 for middle-of-line (MOL) contacts to the gate conductor layer 443 and source/drain regions 435 of the second (e.g., top/upper) nanosheet transistor structures. FIG. 17D shows a top-down view 1775, illustrating where the cross-sectional views 1700 of FIG. 17A, 1750 of FIG. 17B and 1765 of FIG. 17C are taken. The first cross-sectional view 1700 of FIG. 17A is taken across the gate regions 406 along line A-A shown in the top-down view 1775 of FIG. 17D, the second cross-sectional view 1750 of FIG. 17B is taken along one of the gate regions 406 along line B-B shown in the top-down view 1775 of FIG. 17D, and the third cross-sectional view 1765 of FIG. 17C is taken between two of the gate regions 406 along line C-C shown in the top-down view 1775 of FIG. 17D.

The various MOL contact openings 456, 458 and 461 are formed by depositing a frontside interlayer dielectric (ILD) layer 455, and then patterning a mask layer over the frontside ILD layer 455 and etching exposed portions of the frontside ILD layer 455 to form the MOL contact openings. The frontside ILD layer 455 may be formed of any suitable isolating material, such as SiO₂, SiOC, SiON, etc. The MOL contact openings include openings 456 to the gate conductor layer 443, openings 458 to the source/drain regions 435, opening 461 to the source/drain region 435 and the first stage 449 of the multi-stage via. Although not shown, additional openings may be formed to other portions of the structure, such as an opening to source/drain regions 433.

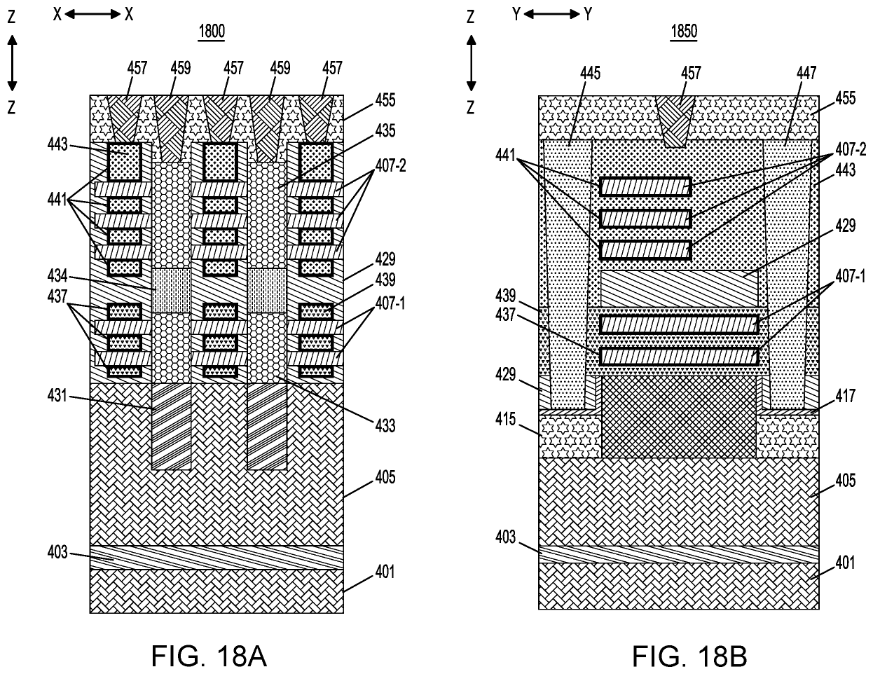

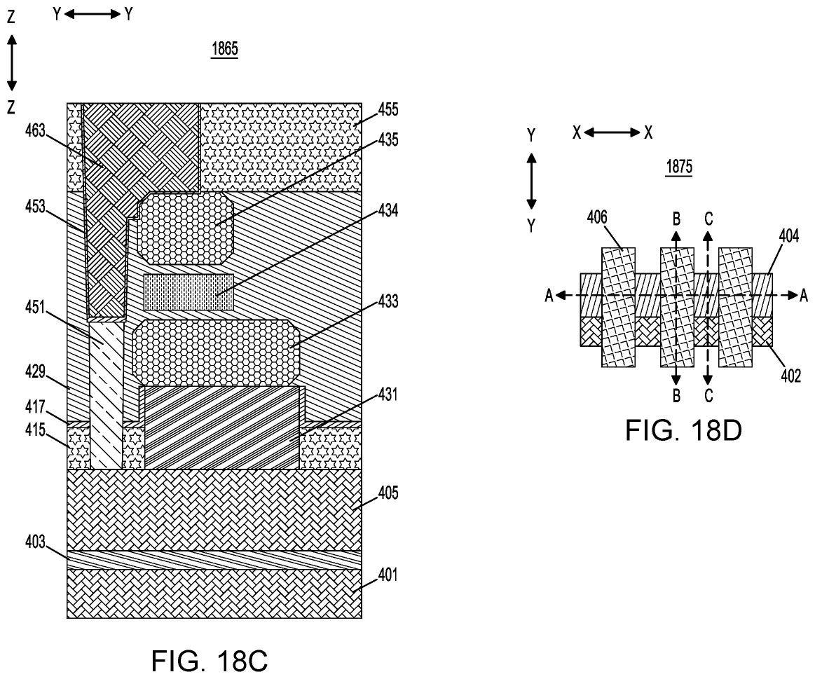

FIGS. 18A, 18B and 18C show respective first, second and third cross-sectional views 1800, 1850 and 1865 of the structure of FIGS. 17A-17D, following formation of MOL contacts 457, 459 and 463 in the MOL contact openings 456, 458 and 461. FIG. 18D shows a top-down view 1875, illustrating where the cross-sectional views 1800 of FIG. 18A, 1850 of FIG. 18B and 1865 of FIG. 18C are taken. The first cross-sectional view 1800 of FIG. 18A is taken across the gate regions 406 along line A-A shown in the top-down view 1875 of FIG. 18D, the second cross-sectional view 1850 of FIG. 18B is taken along one of the gate regions 406 along line B-B shown in the top-down view 1875 of FIG. 18D, and the third cross-sectional view 1865 of FIG. 18C is taken between two of the gate regions 406 along line C-C shown in the top-down view 1875 of FIG. 18D.

The MOL contacts 457, 459 and 463 may be formed by depositing a conductive material in the MOL contact openings 456, 458 and 461. In some embodiments, the MOL contacts 457, 459, and 463 include a silicide layer such as titanium (Ti), nickel (Ni), nickel platinum (NiPt), etc., a metal adhesion layer (e.g., such as TiN) and a low resistance metal such as ruthenium (Ru), tungsten (W), cobalt (Co) or another suitable material.

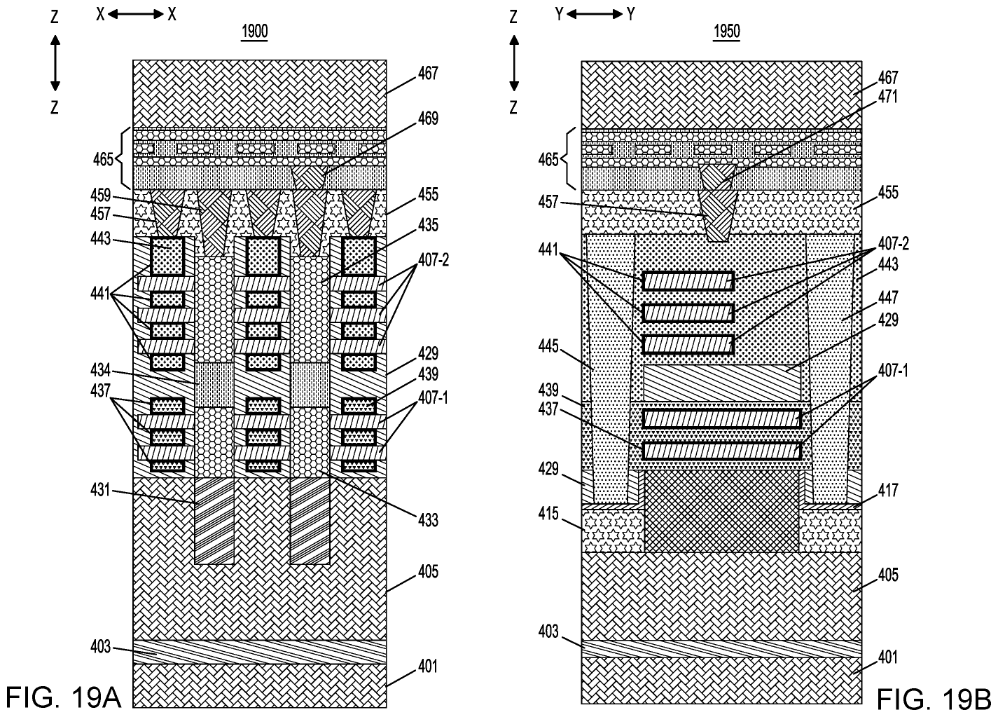

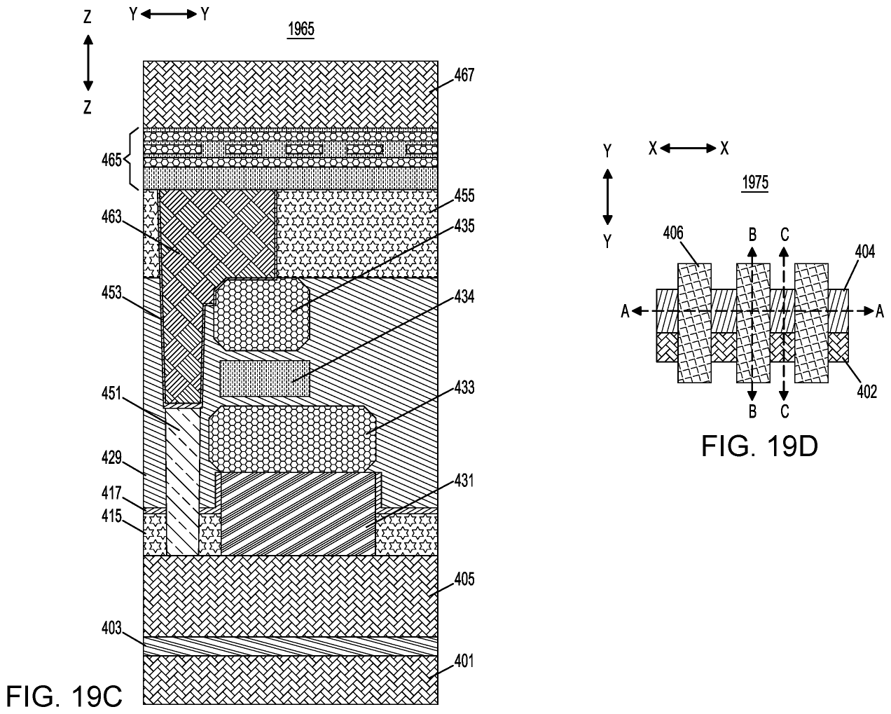

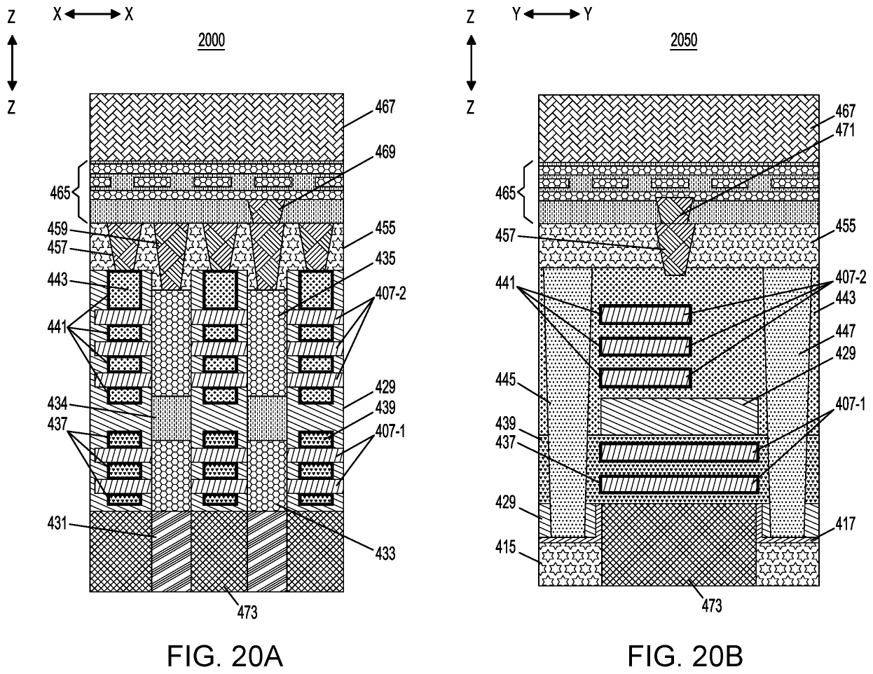

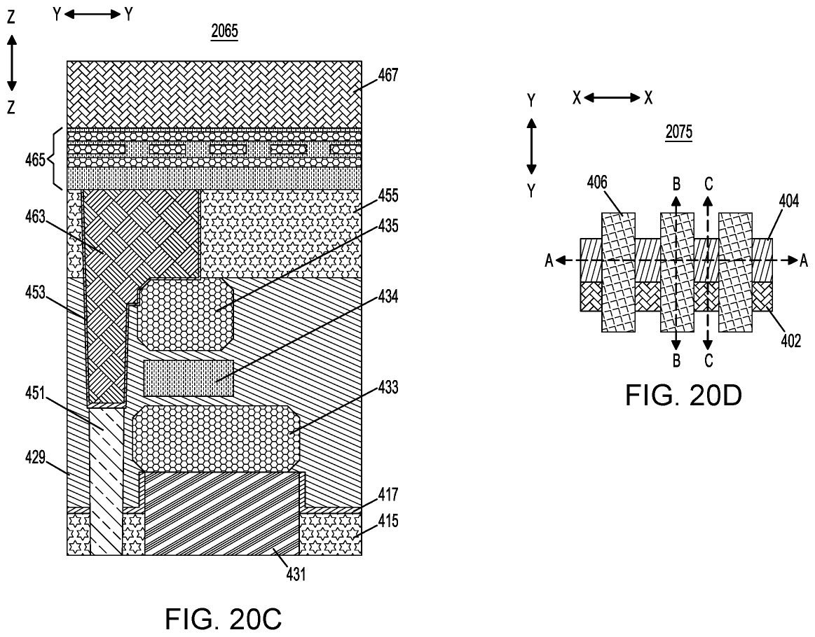

FIGS. 19A, 19B and 19C show respective first, second and third cross-sectional views 1900, 1950 and 1965 of the structure of FIGS. 18A-18D, following formation of a frontside back-end-of-line (BEOL) structure 465 and bonding to a carrier wafer 467. FIG. 19D shows a top-down view 1975, illustrating where the cross-sectional views 1900 of FIG. 20A, 1950 of FIG. 19B and 1965 of FIG. 19C are taken. The first cross-sectional view 1900 of FIG. 19A is taken across the gate regions 406 along line A-A shown in the top-down view 1975 of FIG. 19D, the second cross-sectional view 1950 of FIG. 19B is taken along one of the gate regions 406 along line B-B shown in the top-down view 1975 of FIG. 19D, and the third cross-sectional view 1965 of FIG. 19C is taken between two of the gate regions 406 along line C-C shown in the top-down view 1975 of FIG. 19D.

The frontside BEOL structure 465 includes various BEOL metallization and via layers surrounded by an ILD layer. The BEOL metallization and via layers include a via 469 to one of the MOL contacts 459 to the source/drain regions 435 and a via 471 to one of the MOL contacts 457 to the gate conductor layer 443. The vias 469 and 471 may be formed of the same or similar materials as the MOL contacts 457, 459 and 463. The carrier wafer 467 may be formed of similar materials as the first substrate portion 401 and the second substrate portion 405. The carrier wafer 467 may be formed over the frontside BEOL structure 465 using a wafer bonding process, such as dielectric-to-dielectric bonding.

FIGS. 20A, 20B and 20C show respective first, second and third cross-sectional views 2000, 2050 and 2065 of the structure of FIGS. 20A-20D, following removal of the first substrate portion 401, the etch stop layer 403, and the second substrate portion 405 from the backside of the structure, and following formation of a backside ILD layer 473. FIG. 20D shows a top-down view 2075, illustrating where the cross-sectional views 2000 of FIG. 20A, 2050 of FIG. 20B and 2065 of FIG. 20C are taken. The first cross-sectional view 2000 of FIG. 20A is taken across the gate regions 406 along line A-A shown in the top-down view 2075 of FIG. 20D, the second cross-sectional view 2050 of FIG. 20B is taken along one of the gate regions 406 along line B-B shown in the top-down view 2075 of FIG. 20D, and the third cross-sectional view 2065 of FIG. 20C is taken between two of the gate regions 406 along line C-C shown in the top-down view 2075 of FIG. 20D.

Using the carrier wafer 467, the structure may be “flipped” and the first substrate portion 401, the etch stop layer 403, and the second substrate portion 405 may be removed from the backside. The backside ILD layer 473 is then formed in areas surrounding the sacrificial placeholder layers 431 as illustrated. The backside ILD layer 473 may be formed of similar materials as the frontside ILD layer 455.

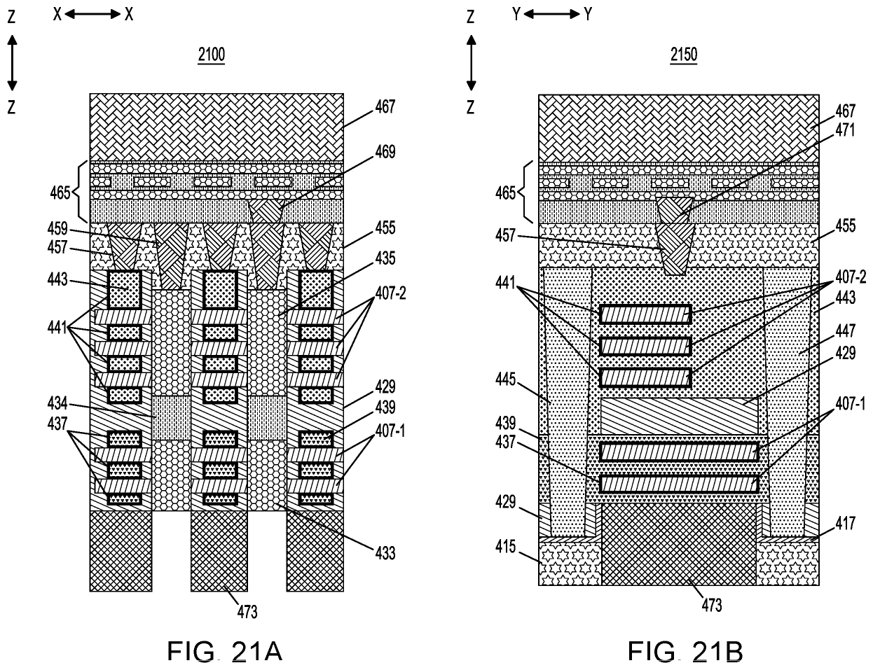

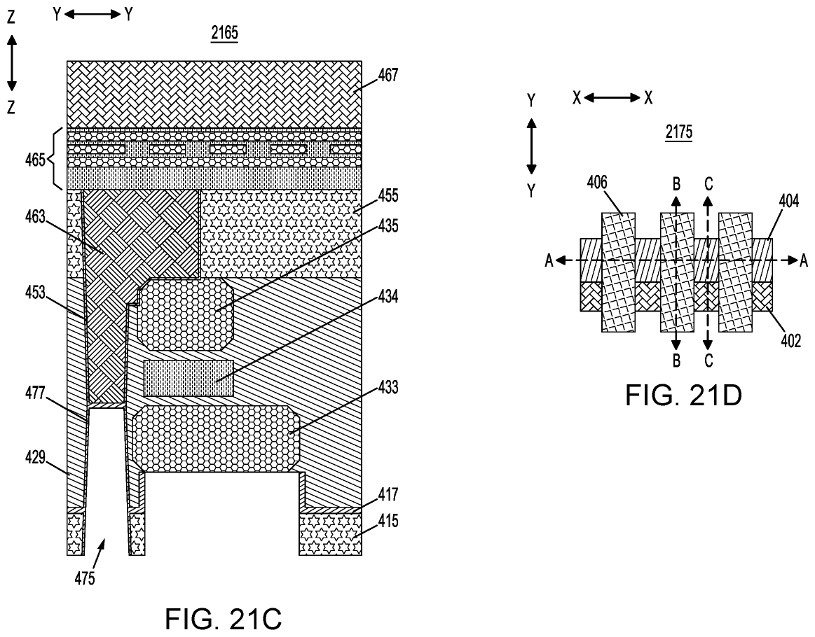

FIGS. 21A, 21B and 21C show respective first, second and third cross-sectional views 2100, 2150 and 2165 of the structure of FIGS. 20A-20D, following removal of the sacrificial placeholder layers 431 and the sacrificial layer 451 from the bottom portion of the first stage 449 of the multi-stage via followed by patterning a second stage or portion 475 of the multi-stage via. FIG. 21D shows a top-down view 2175, illustrating where the cross-sectional views 2100 of FIG. 21A, 2150 of FIG. 21B and 2165 of FIG. 21C are taken. The first cross-sectional view 2100 of FIG. 21A is taken across the gate regions 406 along line A-A shown in the top-down view 2175 of FIG. 21D, the second cross-sectional view 2150 of FIG. 21B is taken along one of the gate regions 406 along line B-B shown in the top-down view 2175 of FIG. 21D, and the third cross-sectional view 2165 of FIG. 21C is taken between two of the gate regions 406 along line C-C shown in the top-down view 2175 of FIG. 21D.

The sacrificial placeholder layers 431 and the sacrificial layer 451 may be removed using RIE or other suitable etch processing. The second stage 475 of the multi-stage via is then formed. This may include forming a barrier layer 477 on sidewalls and the bottom of the second stage 475 of the multi-stage via as illustrated.

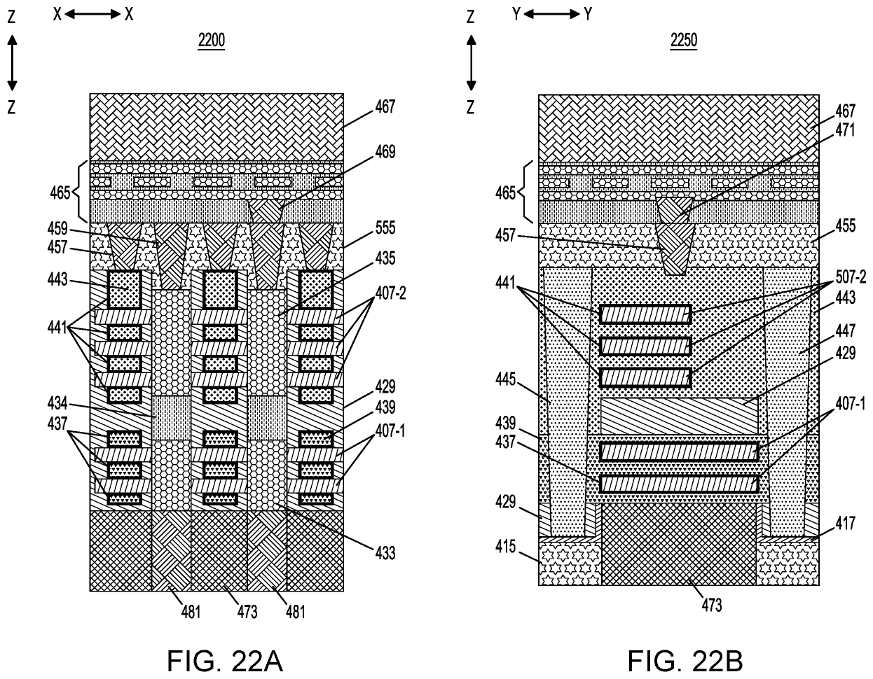

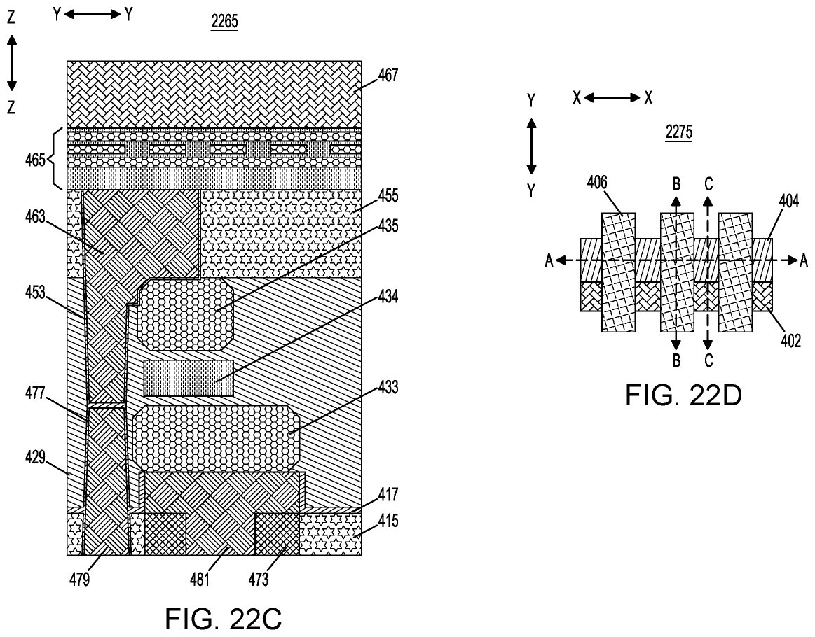

FIGS. 22A, 22B and 22C show respective first, second and third cross-sectional views 2200, 2250 and 2265 of the structure of FIGS. 21A-21D, following fill of contact material 479 in the second stage 475 of the multi-stage via and formation of backside contacts 481. FIG. 22D shows a top-down view 2275, illustrating where the cross-sectional views 2200 of FIG. 22A, 2250 of FIG. 22B and 2265 of FIG. 22C are taken. The first cross-sectional view 2200 of FIG. 22A is taken across the gate regions 406 along line A-A shown in the top-down view 2275 of FIG. 22D, the second cross-sectional view 2250 of FIG. 22B is taken along one of the gate regions 406 along line B-B shown in the top-down view 2275 of FIG. 22D, and the third cross-sectional view 2265 of FIG. 22C is taken between two of the gate regions 406 along line C-C shown in the top-down view 2275 of FIG. 22D.

The backside contacts 481 are filled in the openings in the backside ILD layer 473 (e.g., in regions where the sacrificial placeholder layers 431 and the second substrate portion 405 were previously removed). The backside contacts 481 may be formed of the same or similar materials as the MOL contacts 457, 459 and 463. The same contact material 479 is also deposited in the second stage 475 of the multi-stage via.

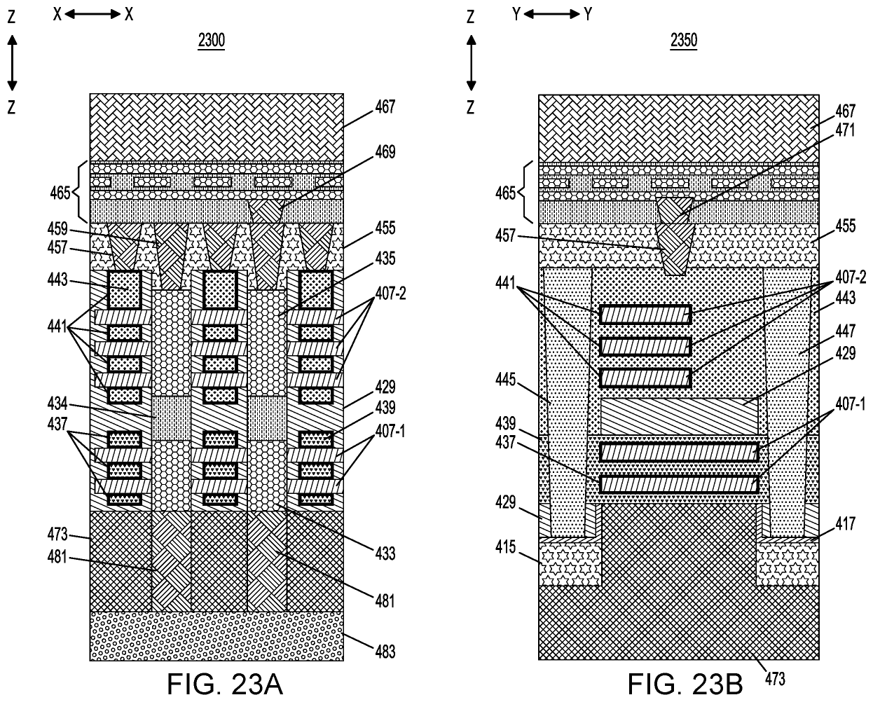

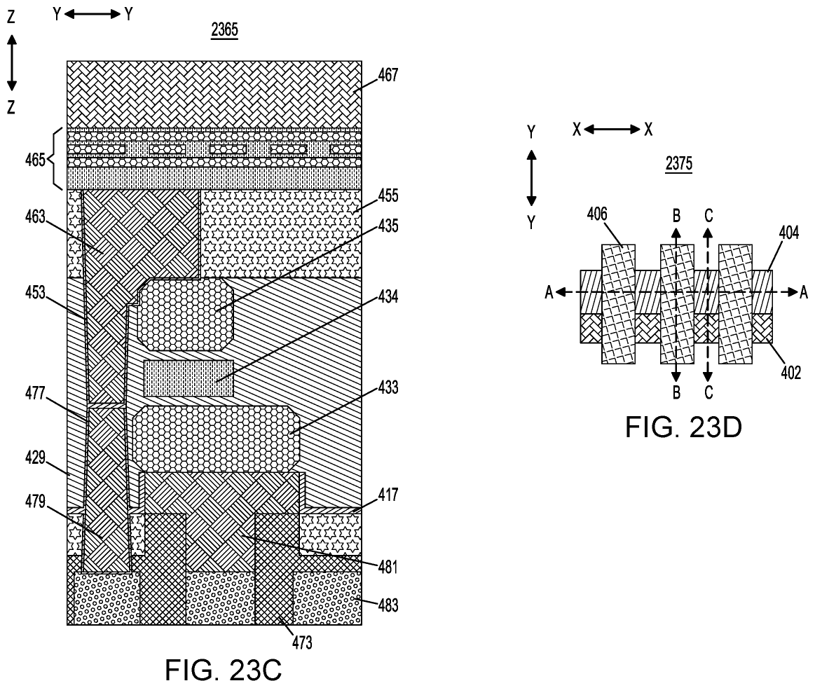

FIGS. 23A, 23B and 23C show respective first, second and third cross-sectional views 2300, 2350 and 2365 of the structure of FIGS. 22A-22D, following formation of backside BEOL structures including backside BEOL metallization layer 483. FIG. 23D shows a top-down view 2375, illustrating where the cross-sectional views 2300 of FIG. 23A, 2350 of FIG. 23B and 2365 of FIG. 23C are taken. The first cross-sectional view 2300 of FIG. 23A is taken across the gate regions 406 along line A-A shown in the top-down view 2375 of FIG. 23D, the second cross-sectional view 2350 of FIG. 23B is taken along one of the gate regions 406 along line B-B shown in the top-down view 2375 of FIG. 23D, and the third cross-sectional view 2365 of FIG. 23C is taken between two of the gate regions 406 along line C-C shown in the top-down view 2375 of FIG. 23D.

The backside BEOL metallization layer 483 is formed and makes contacts to the backside contacts 481 and the backside of the multi-stage via (e.g., the contact material 479). The backside BEOL metallization layer 483 may comprise a power rail (e.g., a VDD/VSS supply), such that the multi-stage via (e.g., including the first stage 449 with the contact material 463 filled from the frontside of the structure and the second stage 475 with the contact material 479 filled from the backside of the structure) provides for backside power delivery to the source/drain regions 435. Although the process flow of FIGS. 4-23D shows formation of just one multi-stage via, embodiments may include one or more other multi-stage vias (e.g., such as one or more “signal” multi-stage vias interconnecting one or more portions of the frontside and backside BEOL structures).

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOSs), metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

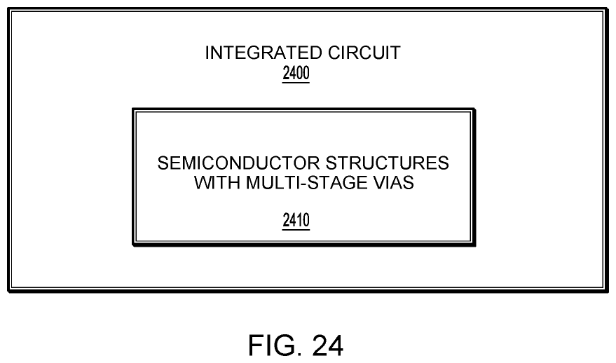

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 24 shows an example integrated circuit 2400 which includes one or more semiconductor structures 2410 with one or more multi-stage vias.

In some embodiments, a semiconductor structure comprises a multi-stage via comprising a first stage and a second stage. The first stage of the multi-stage via has a first surface and a second surface, the first surface of the first stage of the multi-stage via having a first diameter and the second surface of the first stage of the multi-stage via having a second diameter, the second diameter of the second surface of the first stage of the multi-stage via being smaller than or equal to the first diameter of the first surface of the first stage of the multi-stage via. The second stage of the multi-stage via has a first surface and a second surface, the first surface of the second stage of the multi-stage via having a first diameter and the second surface of the second stage of the multi-stage via having a second diameter, the second diameter of the second surface of the second stage of the multi-stage via being smaller than or equal to the first diameter of the first surface of the second stage of the multi-stage via. The first surface of the first stage of the multi-stage via is proximate a first side of the semiconductor structure and the first surface of the second stage of the multi-stage via is proximate a second side of the semiconductor structure, the second side of the semiconductor structure being opposite the first side of the semiconductor structure. The second surface of the first stage of the multi-stage via abuts the second surface of the second stage of the multi-stage via.

The multi-stage via may provide power delivery from a power delivery network at the second side of the semiconductor structure to a portion of a transistor structure proximate the first side of the semiconductor structure. The portion of the transistor structure proximate the first side of the semiconductor structure may comprise a source/drain region of the transistor structure. The transistor structure may comprise a stacked transistor structure comprising a first transistor and a second transistor stacked over the first transistor, and the portion of the transistor structure may comprise a source/drain region of the second transistor. The first transistor and the second transistor may comprise respective nanosheet transistors.

The multi-stage via may provide a signal connection between the first side of the semiconductor structure and the second side of the semiconductor structure. The signal connection may be between a first BEOL structure disposed on the first side of the semiconductor structure and a second BEOL structure disposed on the second side of the semiconductor structure.

The second surface of the first stage of the multi-stage via may abut the second surface of the second stage of the multi-stage via proximate a midpoint between the first side of the semiconductor structure and the second side of the semiconductor structure.

In some embodiments, at least one of the second diameter of the second surface of the first stage of the multi-stage via is smaller than the first diameter of the first surface of the first stage of the multi-stage via and the second diameter of the second surface of the second stage of the multi-stage via is smaller than the first diameter of the first surface of the second stage of the multi-stage via.

In another embodiment, an integrated circuit comprises a semiconductor structure comprising a multi-stage via comprising a first stage and a second stage. The first stage of the multi-stage via has a first surface and a second surface, the first surface of the first stage of the multi-stage via having a first diameter and the second surface of the first stage of the multi-stage via having a second diameter, the second diameter of the second surface of the first stage of the multi-stage via being smaller than or equal to the first diameter of the first surface of the first stage of the multi-stage via. The second stage of the multi-stage via has a first surface and a second surface, the first surface of the second stage of the multi-stage via having a first diameter and the second surface of the second stage of the multi-stage via having a second diameter, the second diameter of the second surface of the second stage of the multi-stage via being smaller than or equal to the first diameter of the first surface of the second stage of the multi-stage via. The first surface of the first stage of the multi-stage via is proximate a first side of the semiconductor structure and the first surface of the second stage of the multi-stage via is proximate a second side of the semiconductor structure, the second side of the semiconductor structure being opposite the first side of the semiconductor structure. The second surface of the first stage of the multi-stage via abuts the second surface of the second stage of the multi-stage via.

The multi-stage via may provide power delivery from a power delivery network at the second side of the semiconductor structure to a portion of a transistor structure proximate the first side of the semiconductor structure.

The multi-stage via may provide a signal connection between the first side of the semiconductor structure and the second side of the semiconductor structure.

The second surface of the first stage of the multi-stage via may abut the second surface of the second stage of the multi-stage via proximate a midpoint between the first side of the semiconductor structure and the second side of the semiconductor structure.

In another embodiment, a semiconductor structure comprises a stacked transistor structure comprising a first transistor vertically stacked over a second transistor and a multi-stage via comprising a first stage and a second stage. The first transistor is proximate a first side of the semiconductor structure and the second transistor is proximate a second side of the semiconductor structure opposite the first side of the semiconductor structure. Each of the first stage and the second stage of the multi-stage via has a first surface and a second surface opposite the first surface, the first surface of the first stage of the multi-stage via being proximate the first side of the semiconductor structure, the first surface of the first stage of the multi-stage via being proximate the second side of the semiconductor structure, and the second surface of the first stage of the multi-stage via abutting the second surface of the second stage of the multi-stage via. The multi-stage via connects a power delivery network proximate the second side of the semiconductor structure to a source/drain region of the first transistor. A first diameter of the first surface of the first stage of the multi-stage via is greater than or equal to a second diameter of the second surface of the second stage of the multi-stage via. A first diameter of the first surface of the second stage of the multi-stage via is greater than or equal to a second diameter of the second surface of the second stage of the multi-stage via.

The first transistor and the second transistor may comprise respective nanosheet transistors.

The second surface of the first stage of the multi-stage via may abut the second surface of the second stage of the multi-stage via proximate a midpoint between the first side of the semiconductor structure and the second side of the semiconductor structure.

In another embodiment, a semiconductor structure comprises a first BEOL structure proximate a first side of the semiconductor structure, a second BEOL structure proximate a second side of the semiconductor structure opposite the first side of the semiconductor structure, and a multi-stage via comprising a first stage and a second stage, each of the first stage and the second stage having a first surface and a second surface opposite the first surface, the first surface of the first stage of the multi-stage via being proximate the first side of the semiconductor structure, the first surface of the first stage of the multi-stage via being proximate the second side of the semiconductor structure, and the second surface of the first stage of the multi-stage via abutting the second surface of the second stage of the multi-stage via. The multi-stage via provides a signal connection between the first BEOL structure and the second BEOL structure. A first diameter of the first surface of the first stage of the multi-stage via is greater than or equal to a second diameter of the second surface of the second stage of the multi-stage via. A first diameter of the first surface of the second stage of the multi-stage via is greater than or equal to a second diameter of the second surface of the second stage of the multi-stage via.

The multi-stage via may provide the signal connection between a first metallization layer of the first BEOL structure and a second metallization layer of the second BEOL structure.

The second surface of the first stage of the multi-stage via may abut the second surface of the second stage of the multi-stage via proximate a midpoint between the first side of the semiconductor structure and the second side of the semiconductor structure.

In another embodiment, a method comprises forming a first stage of a multi-stage via in a semiconductor structure utilizing processing from a first side of the semiconductor structure, the first stage of the multi-stage via having a first surface and a second surface opposite the first surface. The method also comprises forming a second stage of the multi-stage via in the semiconductor structure utilizing processing from a second side of the semiconductor structure, the first stage of the multi-stage via having a first surface and a second surface opposite the first surface. The first surface of the first stage of the multi-stage via is proximate the first side of the semiconductor structure, the first surface of the second stage of the multi-stage via is proximate the second side of the semiconductor structure, and the second surface of the first stage of the multi-stage via abuts the second surface of the second stage of the multi-stage via.

A first diameter of the first surface of the first stage of the multi-stage via may be greater than or equal to a second diameter of the second surface of the second stage of the multi-stage via, and a first diameter of the first surface of the second stage of the multi-stage via may be greater than or equal to a second diameter of the second surface of the second stage of the multi-stage via.

The second surface of the first stage of the multi-stage via may abut the second surface of the second stage of the multi-stage via proximate a midpoint between the first side of the semiconductor structure and the second side of the semiconductor structure.

Forming the second stage of the multi-stage via may be co-integrated with formation of contacts to one or more portions of a transistor structure from the second side of the semiconductor structure. The contacts to the one or more portions of the transistor structure may comprise contacts to a first source/drain region of the transistor structure, and the first stage of the multi-stage via may connect to a contact to a second source/drain region of the transistor structure. The transistor structure may comprise a stacked transistor structure comprising a first transistor and a second transistor stacked vertically over the first transistor, the first source/drain region may comprise a source/drain region of the first transistor and the second source/drain region may comprise a source/drain region of the second transistor.

The second surface of the second stage of the multi-stage via may be connected to a backside power delivery network disposed proximate the second side of the semiconductor structure.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a multi-stage via comprising a first stage and a second stage;
the first stage of the multi-stage via having a first surface and a second surface, the first surface of the first stage of the multi-stage via having a first diameter and the second surface of the first stage of the multi-stage via having a second diameter, the second diameter of the second surface of the first stage of the multi-stage via being smaller than or equal to the first diameter of the first surface of the first stage of the multi-stage via;
the second stage of the multi-stage via having a first surface and a second surface, the first surface of the second stage of the multi-stage via having a first diameter and the second surface of the second stage of the multi-stage via having a second diameter, the second diameter of the second surface of the second stage of the multi-stage via being smaller than or equal to the first diameter of the first surface of the second stage of the multi-stage via;
wherein the first surface of the first stage of the multi-stage via is proximate a first side of the semiconductor structure and the first surface of the second stage of the multi-stage via is proximate a second side of the semiconductor structure, the second side of the semiconductor structure being opposite the first side of the semiconductor structure; and
wherein the second surface of the first stage of the multi-stage via abuts the second surface of the second stage of the multi-stage via.

2. The semiconductor structure of claim 1, wherein the multi-stage via provides power delivery from a power delivery network at the second side of the semiconductor structure to a portion of a transistor structure proximate the first side of the semiconductor structure.

3. The semiconductor structure of claim 2, wherein the portion of the transistor structure proximate the first side of the semiconductor structure comprises a source/drain region of the transistor structure.

4. The semiconductor structure of claim 2, wherein the transistor structure comprises a stacked transistor structure comprising a first transistor and a second transistor stacked over the first transistor, and wherein the portion of the transistor structure comprises a source/drain region of the second transistor.

5. The semiconductor structure of claim 4 wherein the first transistor and the second transistor comprise respective nanosheet transistors.

6. The semiconductor structure of claim 1, wherein the multi-stage via provides a signal connection between the first side of the semiconductor structure and the second side of the semiconductor structure.

7. The semiconductor structure of claim 6, wherein the signal connection is between a first back-end-of-line structure disposed on the first side of the semiconductor structure and a second back-end-of-line structure disposed on the second side of the semiconductor structure.

8. The semiconductor structure of claim 1, wherein the second surface of the first stage of the multi-stage via abuts the second surface of the second stage of the multi-stage via proximate a midpoint between the first side of the semiconductor structure and the second side of the semiconductor structure.

9. The semiconductor structure of claim 1, wherein at least one of:
the second diameter of the second surface of the first stage of the multi-stage via is smaller than the first diameter of the first surface of the first stage of the multi-stage via; and
the second diameter of the second surface of the second stage of the multi-stage via is smaller than the first diameter of the first surface of the second stage of the multi-stage via.

10. An integrated circuit comprising:
a semiconductor structure comprising:
a multi-stage via comprising a first stage and a second stage;
the first stage of the multi-stage via having a first surface and a second surface, the first surface of the first stage of the multi-stage via having a first diameter and the second surface of the first stage of the multi-stage via having a second diameter, the second diameter of the second surface of the first stage of the multi-stage via being smaller than or equal to the first diameter of the first surface of the first stage of the multi-stage via;
the second stage of the multi-stage via having a first surface and a second surface, the first surface of the second stage of the multi-stage via having a first diameter and the second surface of the second stage of the multi-stage via having a second diameter, the second diameter of the second surface of the second stage of the multi-stage via being smaller than or equal to the first diameter of the first surface of the second stage of the multi-stage via;
wherein the first surface of the first stage of the multi-stage via is proximate a first side of the semiconductor structure and the first surface of the second stage of the multi-stage via is proximate a second side of the semiconductor structure, the second side of the semiconductor structure being opposite the first side of the semiconductor structure; and
wherein the second surface of the first stage of the multi-stage via abuts the second surface of the second stage of the multi-stage via.

11. The integrated circuit of claim 10, wherein the multi-stage via provides power delivery from a power delivery network at the second side of the semiconductor structure to a portion of a transistor structure proximate the first side of the semiconductor structure.

12. The integrated circuit of claim 10, wherein the multi-stage via provides a signal connection between the first side of the semiconductor structure and the second side of the semiconductor structure.

13. The integrated circuit of claim 10, wherein the second surface of the first stage of the multi-stage via abuts the second surface of the second stage of the multi-stage via proximate a midpoint between the first side of the semiconductor structure and the second side of the semiconductor structure.

14. A semiconductor structure, comprising:
a stacked transistor structure comprising a first transistor vertically stacked over a second transistor, the first transistor being proximate a first side of the semiconductor structure and the second transistor being proximate a second side of the semiconductor structure opposite the first side of the semiconductor structure;
a multi-stage via comprising a first stage and a second stage, each of the first stage and the second stage having a first surface and a second surface opposite the first surface, the first surface of the first stage of the multi-stage via being proximate the first side of the semiconductor structure, the first surface of the first stage of the multi-stage via being proximate the second side of the semiconductor structure, and the second surface of the first stage of the multi-stage via abutting the second surface of the second stage of the multi-stage via;
wherein the multi-stage via connects a power delivery network proximate the second side of the semiconductor structure to a source/drain region of the first transistor;
wherein a first diameter of the first surface of the first stage of the multi-stage via is greater than or equal to a second diameter of the second surface of the second stage of the multi-stage via; and
wherein a first diameter of the first surface of the second stage of the multi-stage via is greater than or equal to a second diameter of the second surface of the second stage of the multi-stage via.

15. The semiconductor structure of claim 14, wherein the first transistor and the second transistor comprise respective nanosheet transistors.

16. The semiconductor structure of claim 14, wherein the second surface of the first stage of the multi-stage via abuts the second surface of the second stage of the multi-stage via proximate a midpoint between the first side of the semiconductor structure and the second side of the semiconductor structure.

17. A semiconductor structure, comprising:
a first back-end-of-line structure proximate a first side of the semiconductor structure;
a second back-end-of-line structure proximate a second side of the semiconductor structure opposite the first side of the semiconductor structure; and
a multi-stage via comprising a first stage and a second stage, each of the first stage and the second stage having a first surface and a second surface opposite the first surface, the first surface of the first stage of the multi-stage via being proximate the first side of the semiconductor structure, the first surface of the first stage of the multi-stage via being proximate the second side of the semiconductor structure, and the second surface of the first stage of the multi-stage via abutting the second surface of the second stage of the multi-stage via;
wherein the multi-stage via provides a signal connection between the first back-end-of-line structure and the second back-end-of-line structure;
wherein a first diameter of the first surface of the first stage of the multi-stage via is greater than or equal to a second diameter of the second surface of the second stage of the multi-stage via; and
wherein a first diameter of the first surface of the second stage of the multi-stage via is greater than or equal to a second diameter of the second surface of the second stage of the multi-stage via.

18. The semiconductor structure of claim 17, wherein the multi-stage via provides the signal connection between a first metallization layer of the first back-end-of-line structure and a second metallization layer of the second back-end-of-line structure.

19. The semiconductor structure of claim 17, wherein the second surface of the first stage of the multi-stage via abuts the second surface of the second stage of the multi-stage via proximate a midpoint between the first side of the semiconductor structure and the second side of the semiconductor structure.

20. A method comprising:
forming a first stage of a multi-stage via in a semiconductor structure utilizing processing from a first side of the semiconductor structure, the first stage of the multi-stage via having a first surface and a second surface opposite the first surface; and
forming a second stage of the multi-stage via in the semiconductor structure utilizing processing from a second side of the semiconductor structure, the first stage of the multi-stage via having a first surface and a second surface opposite the first surface;
wherein the first surface of the first stage of the multi-stage via is proximate the first side of the semiconductor structure, the first surface of the second stage of the multi-stage via is proximate the second side of the semiconductor structure, and the second surface of the first stage of the multi-stage via abuts the second surface of the second stage of the multi-stage via.

21. The method of claim 20, wherein a first diameter of the first surface of the first stage of the multi-stage via is greater than or equal to a second diameter of the second surface of the second stage of the multi-stage via, and wherein a first diameter of the first surface of the second stage of the multi-stage via is greater than or equal to a second diameter of the second surface of the second stage of the multi-stage via.

22. The method of claim 20, wherein the second surface of the first stage of the multi-stage via abuts the second surface of the second stage of the multi-stage via proximate a midpoint between the first side of the semiconductor structure and the second side of the semiconductor structure.

23. The method of claim 20, wherein forming the second stage of the multi-stage via is co-integrated with formation of contacts to one or more portions of a transistor structure from the second side of the semiconductor structure, wherein the contacts to the one or more portions of the transistor structure comprise contacts to a first source/drain region of the transistor structure, and wherein the first stage of the multi-stage via connects to a contact to a second source/drain region of the transistor structure.

24. The method of claim 23, wherein the transistor structure comprises a stacked transistor structure comprising a first transistor and a second transistor stacked vertically over the first transistor, and wherein the first source/drain region comprises a source/drain region of the first transistor and the second source/drain region comprises a source/drain region of the second transistor.

25. The method of claim 20, wherein the second surface of the second stage of the multi-stage via is connected to a backside power delivery network disposed proximate the second side of the semiconductor structure.
